(19) United States
(12) Patent Application Publication
(10) Pub. No.: US 2026/0362837 A1
(43) Pub. Date: Nov. 12, 2026

(54) LIGHT DETECTION DEVICE, METHOD FOR MANUFACTURING LIGHT DETECTION DEVICE, AND ELECTRONIC APPARATUS

(71) Applicant: SONY SEMICONDUCTOR SOLUTIONS CORPORATION, KANAGAWA (JP)

(72) Inventors: Yoshinori KODAMA, KANAGAWA (JP); Takayoshi HONDA, KANAGAWA (JP); Toshinori INOUE, KANAGAWA (JP)

(21) Appl. No.: 19/109,236

(22) PCT Filed: Feb. 27, 2023
(86) PCT No.: PCT/JP2023/027645

§ 371 Date: Mar. 6, 2025

(30) Foreign Application Priority Data
Sep. 14, 2022 (JP) 2022-146323

(51) Int. Cl. H10F 39/00; H10F 39/18

(52) U.S. Cl. CPC H10F 39/807; H10F 39/18; H10F 39/8063

(57) ABSTRACT

Provided is a light detection device that has a pixel structure where an on-chip lens is formed for each group of pixels and allows a reduction in the number of processes for an inter-pixel isolation section and a reduction of light scattering. The light detection device includes a semiconductor substrate, a pixel isolation section, and an on-chip lens. The pixel isolation section is provided in the semiconductor substrate to isolate the pixels adjacent to each other. The on-chip lens is arranged on the light incident surface side of the semiconductor substrate for each pixel group including at least two of the plurality of pixels and condenses light from the outside onto the pixel group. The pixel isolation section includes an intra-pixel group isolation section arranged between the pixels adjacent to each other of the pixel group and including a first recessed region extending in the thickness direction of the semiconductor substrate and a second recessed region that is different from the first recessed region and is located at a focal position of light condensed by the on-chip lens. In the intra-pixel group isolation section, the second recessed region is formed narrower than the first recessed region in plan view.

### TECHNICAL FIELD

The technology (present technology) according to the present disclosure relates to a light detection device, a method for manufacturing a light detection device, and an electronic apparatus including a light detection device.

### BACKGROUND ART

Conventionally, in an electronic apparatus having an imaging function such as a digital still camera or a digital video camera, for example, a solid-state imaging element such as a charge coupled device (CCD) or a complementary metal oxide semiconductor (CMOS) image sensor is used as a light detection device. The light detection device includes a pixel in which a photodiode (photoelectric conversion element) that performs photoelectric conversion and a transistor are combined, and an image is constructed on the basis of pixel signals output from a plurality of pixels arranged in a plane.

Meanwhile, in a case where strong light is incident on a pixel, there is a possibility that charges accumulated in the photodiode of the pixel are saturated and overflow into adjacent pixels, causing a phenomenon known as color mixing. A solid-state imaging device in which pixels are isolated by a through trench has been considered, but the through trench is formed between all pixels, so that it is necessary to form, for each pixel, a well contact used to supply a ground potential. Therefore, a solid-state imaging device has been proposed in which a non-through trench is formed at an area where an element such as a transistor is arranged between pixels (for example, Patent Document 1).

### CITATION LIST

### Patent Document

Patent Document 1: Japanese Patent Application Laid-Open No. 2019-145544

### SUMMARY OF THE INVENTION

### Problems to be Solved by the Invention

For the solid-state imaging device disclosed in Patent Document 1, the through trench and the non-through trench, however, are separately formed, resulting in an increase in the number of processes. Furthermore, misalignment at the joint between the through trench and the non-through trench leads to double processing or trench separation.

Moreover, a structure where a single on-chip lens is shared by a plurality of pixels suffers light scattering due to a non-through trench at the center of the on-chip lens.

The present disclosure has been made in view of such circumstances, and it is therefore an object of the present disclosure to provide a light detection device that has a pixel structure where an on-chip lens is formed for each group of pixels and allows a reduction in the number of processes for a pixel isolation section and a reduction of light scattering, a method for manufacturing a light detection device, and an electronic apparatus.

### Solutions to Problems

A light detection device according to an aspect of the present disclosure includes: a semiconductor substrate in which a plurality of pixels capable of generating an electric signal according to light incident from an outside is arranged in a matrix; a pixel isolation section provided in the semiconductor substrate to isolate the pixels adjacent to each other; and an on-chip lens arranged on a light incident surface side of the semiconductor substrate for each pixel group including at least two of the plurality of pixels, the on-chip lens being configured to condense the light from the outside onto the pixel group, in which the pixel isolation section includes an intra-pixel group isolation section arranged between the pixels adjacent to each other of the pixel group and including a first recessed region extending in a thickness direction of the semiconductor substrate and a second recessed region located at a focal position of the light condensed by the on-chip lens, the second recessed region being different from the first recessed region, and, in the intra-pixel group isolation section, the second recessed region is formed narrower than the first recessed region in plan view.

A light detection device according to another aspect of the present disclosure includes: a semiconductor substrate in which a plurality of pixels capable of generating an electric signal according to light incident from an outside is arranged in a matrix; a pixel isolation section provided in the semiconductor substrate to isolate the pixels adjacent to each other; and an on-chip lens arranged on a light incident surface side of the semiconductor layer for each pixel group including at least two pixels of the same color, the on-chip lens being configured to condense the light from the outside onto the pixel group, in which the pixel isolation section includes an intra-pixel group isolation section arranged between the pixels adjacent to each other of the pixel group and having an opening at least in a part of a focal position of the light condensed by the on-chip lens, the on-chip lens is arranged to be shifted in a predetermined direction from a center of the pixel group according to a pupil correction position, and a formation position of the opening of the intra-pixel group isolation section is shifted according to the pupil correction position.

A method for manufacturing a light detection device according to another aspect of the present disclosure, the light detection device including: a semiconductor substrate in which a plurality of pixels capable of generating an electric signal according to light incident from an outside is arranged in a matrix; a pixel isolation section provided in the semiconductor substrate to isolate the pixels adjacent to each other; and an on-chip lens arranged on a light incident surface side of the semiconductor substrate for each pixel group including at least two pixels of the same color, the on-chip lens being configured to condense the light from the outside onto the pixel group, the method including: a first process of forming an intra-pixel group isolation section between the pixels adjacent to each other of the pixel group and including a first recessed region extending in a thickness direction of the semiconductor substrate and a second recessed region located at a focal position of the light condensed by the on-chip lens, the second recessed region being different from the first recessed region, in which in the first process, the second recessed region is formed narrower than the first recessed region in plan view.

### BRIEF DESCRIPTION OF DRAWINGS

FIG. 1 is a block diagram illustrating an example of a schematic configuration of a light detection device according to a first embodiment of the present disclosure.

FIG. 2 is a circuit configuration diagram of a pixel illustrated in FIG. 1.

FIG. 3 is a partial longitudinal cross-sectional view illustrating an example of a semiconductor structure of the light detection device according to the first embodiment of the present disclosure.

FIG. 4 is a plan view illustrating a configuration example of a pixel layout according to the first embodiment of the present disclosure and an arrangement example of an on-chip lens with respect to the pixel layout.

FIG. 5 is a partial longitudinal cross-sectional view illustrating an example of a semiconductor structure in schematic cross section taken along a line B1-B1′ of a pixel group illustrated in FIG. 4.

FIG. 6 is a plan view illustrating a configuration example of a pixel layout according to a second embodiment of the present disclosure and an arrangement example of an on-chip lens with respect to the pixel layout.

FIG. 7 is a partial longitudinal cross-sectional view illustrating an example of a semiconductor structure in schematic cross section taken along a line B2-B2′ of a pixel group illustrated in FIG. 6.

FIG. 8 is a cross-sectional view specifically illustrating a through region according to the second embodiment.

FIG. 9 is a plan view illustrating a configuration example of a pixel layout according to a third embodiment of the present disclosure and an arrangement example of an on-chip lens with respect to the pixel layout.

FIG. 10 is a plan view illustrating a configuration example of a pixel layout according to a fourth embodiment of the present disclosure and an arrangement example of an on-chip lens with respect to the pixel layout.

FIG. 11A is a plan view of a light detection device according to a fifth embodiment as viewed from a back surface side and a partial cross-sectional view illustrating an example of a semiconductor structure of the light detection device taken along a line C1-C1′ (part 1).

FIG. 11B is a plan view of the light detection device according to the fifth embodiment as viewed from the back surface side and a partial cross-sectional view illustrating an example of the semiconductor structure of the light detection device taken along the line C1-C1′ (part 2).

FIG. 11C is a plan view of the light detection device according to the fifth embodiment as viewed from the back surface side and a partial cross-sectional view illustrating an example of the semiconductor structure of the light detection device taken along the line C1-C1′ (part 3).

FIG. 12A is a plan view of a light detection device according to a sixth embodiment as viewed from a back surface side and a partial cross-sectional view illustrating an example of a semiconductor structure of the light detection device taken along a line D1-D1′ (part 1).

FIG. 12B is a plan view of the light detection device according to the sixth embodiment as viewed from the back surface side and a partial cross-sectional view illustrating an example of the semiconductor structure of the light detection device taken along the line D1-D1′ (part 2).

FIG. 12C is a plan view of the light detection device according to the sixth embodiment as viewed from the back surface side and a partial cross-sectional view illustrating an example of the semiconductor structure of the light detection device taken along the line D1-D1′ (part 3).

FIG. 13 is a plan view illustrating a configuration example of a pixel layout of a light detection device according to a seventh embodiment of the present disclosure.

FIG. 14 is a plan view illustrating a configuration example of a pixel layout of a light detection device according to a comparative example of the seventh embodiment.

FIG. 15 is a plan view illustrating a configuration example of a pixel layout of a light detection device according to an eighth embodiment of the present disclosure.

FIG. 16A is a plan view of the light detection device according to the seventh embodiment as viewed from a back surface side and a partial cross-sectional view illustrating an example of a semiconductor structure of the light detection device taken along a line G1-G1′ (part 1).

FIG. 16B is a plan view of the light detection device according to the seventh embodiment as viewed from the back surface side and a partial cross-sectional view illustrating an example of the semiconductor structure of the light detection device taken along the line G1-G1′ (part 2).

FIG. 16C is a plan view of the light detection device according to the seventh embodiment as viewed from the back surface side and a partial cross-sectional view illustrating an example of the semiconductor structure of the light detection device taken along the line G1-G1′ (part 3).

FIG. 17 is a plan view illustrating a configuration example of a pixel layout according to a tenth embodiment of the present disclosure and an arrangement example of an on-chip lens with respect to the pixel layout.

FIG. 18 is a partial cross-sectional view illustrating an example of a semiconductor structure of the light detection device taken along a line H1-H1′ in FIG. 17.

FIG. 19 is a cross-sectional view illustrating a configuration example of a pixel layout according to an eleventh embodiment of the present disclosure and an arrangement example of an on-chip lens with respect to the pixel layout.

FIG. 20A is a partial cross-sectional view illustrating an example of a semiconductor structure of a light detection device according to a twelfth embodiment (part 1).

FIG. 20B is a partial cross-sectional view illustrating an example of the semiconductor structure of the light detection device according to the twelfth embodiment (part 2).

FIG. 20C is a partial cross-sectional view illustrating an example of the semiconductor structure of the light detection device according to the twelfth embodiment (part 3).

FIG. 20D is a partial cross-sectional view illustrating an example of the semiconductor structure of the light detection device according to the twelfth embodiment (part 4).

FIG. 21 is a block diagram illustrating a configuration example of an imaging device as an electronic apparatus to which the present technology is applied.

FIG. 22 is a block diagram illustrating a schematic configuration example of a vehicle control system, which is an example of a mobile structure control system to which the technology according to the present disclosure can be applied.

FIG. 23 is a diagram illustrating an example of an installation position of an imaging section illustrated in FIG. 22.

### MODE FOR CARRYING OUT THE INVENTION

Hereinafter, embodiments of the present disclosure will be described with reference to the drawings. In the illustration of the drawings referred to in the following description, the same or similar components are denoted by the same or similar reference signs to avoid the description from being redundant.

It should be noted that the drawings are schematic, and the relationship between thickness and planar dimension, the ratio of thickness of each device or each member, and the like differ from actual ones. Therefore, specific thicknesses and dimensions should be determined in consideration of the following description. Furthermore, it goes without saying that dimensional relationships and ratios are partly different between the drawings.

Herein, a “first conductivity type” means one of a p-type or an n-type, and a “second conductivity type” means one of the p-type or the n-type different from the “first conductivity type”. Furthermore, “+” or “-” added to “n” or “p” means a semiconductor region that is higher or lower in impurity density than a semiconductor region to which neither “+” nor “−” is added. It should be noted that even semiconductor regions to which the same “n” and “n” are added do not necessarily mean that the semiconductor regions are exactly the same in impurity density.

Furthermore, the definitions of directions such as up and down in the following description are merely given for convenience of description and are not intended to limit the technical idea of the present disclosure. For example, it goes without saying that when an object is observed by rotating the object by 90°, the up and down are converted into left and right, and when the object is observed by rotating the object by 180°, the up and down are inverted.

Note that the effects described herein are merely examples and are not restrictive, and there may be other effects.

### First Embodiment

### Overall Configuration of Light Detection Device

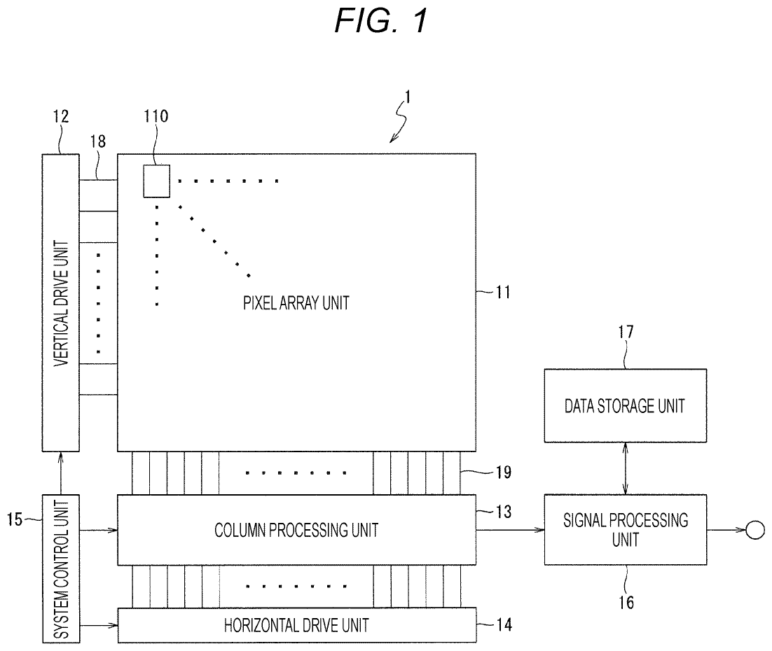

FIG. 1 is a block diagram illustrating an example of a schematic configuration of a light detection device according to a first embodiment of the present disclosure. A light detection device 1 is a semiconductor device that converts a charge amount corresponding to the intensity of light formed as an image on each pixel into an electric signal using a photoelectric conversion element such as a photodiode that is a component of each pixel, and outputs the electric signal as image data, and is configured as, for example, a CMOS image sensor. The light detection device 1 can be integrally configured as, for example, a system on a chip (SoC) such as a CMOS LSI, but for example, some components described below may be configured as separate LSIS.

As illustrated in the drawing, the light detection device 1 includes components such as a pixel array unit 11, a vertical drive unit 12, a column processing unit 13, a horizontal drive unit 14, a system control unit 15, a signal processing unit 16, and a data storage unit 17.

The pixel array unit 11 includes photoelectric conversion element groups such as photodiodes that are components of pixels 110 arrayed in a horizontal direction (row direction) and a vertical direction (column direction). The pixel array unit 11 converts a charge amount corresponding to the intensity of incident light formed as an image on each pixel 110 into an electric signal and outputs the electric signal as a pixel signal. The pixel array unit 11 can include, for example, effective pixels arranged in a region capable of receiving actual light and dummy pixels arranged outside the region and shielded by metal or the like. Note that an optical element such as a micro-on-chip lens or a color filter that condenses incident light is formed on each pixel 110 of the pixel array unit 11 (not illustrated). A region occupied by the arrayed pixels 110 serves as a so-called “image height” corresponding to a target space to be imaged.

The vertical drive unit 12 includes a shift register, an address decoder, and the like. The vertical drive unit 12 supplies a drive signal or the like to each pixel 110 through a plurality of pixel drive lines 18, thereby driving each pixel 110 of the pixel array unit 11, for example, simultaneously or row by row.

The column processing unit 13 reads a pixel signal from each pixel through a vertical signal line (VSL) 19 for each pixel column (column) of the pixel array unit 11, and performs noise removal processing, correlated double sampling (CDS) processing, analog-to-digital (A/D) conversion processing, and the like. The pixel signal processed by the column processing unit 13 is output to the signal processing unit 16.

The horizontal drive unit 14 includes a shift register, an address decoder, and the like. The horizontal drive unit 14 sequentially selects the pixels 110 corresponding to the pixel columns of the column processing unit 13. As a result of the selective scanning by the horizontal drive unit 14, the pixel signals subjected to the signal processing for each pixel 110 in the column processing unit 13 are sequentially output to the signal processing unit 16.

The system control unit 15 includes a timing generator that generates various timing signals and the like. The system control unit 15 performs drive control of the vertical drive unit 12, the column processing unit 13, and the horizontal drive unit 14 on the basis of, for example, the timing signals generated by the timing generator (not illustrated).

The signal processing unit 16 performs signal processing such as arithmetic processing or the like on the pixel signal supplied from the column processing unit 13 while temporarily storing data in the data storage unit 17 as necessary, and outputs an image signal based on each pixel signal. Furthermore, the signal processing unit 16 performs signal processing according to a flag output from the column processing unit 13.

Note that the light detection device 1 to which the present technology is applied is not limited to the configuration as described above. For example, the light detection device 1 may be configured such that the data storage unit 17 is arranged downstream of the column processing unit 13, and the pixel signal output from the column processing unit 13 is supplied to the signal processing unit 16 via the data storage unit 17. Alternatively, the light detection device 1 may be configured such that the column processing unit 13, the data storage unit 17, and the signal processing unit 16 connected in cascade process the respective pixel signals in parallel.

### Pixel Circuit Configuration

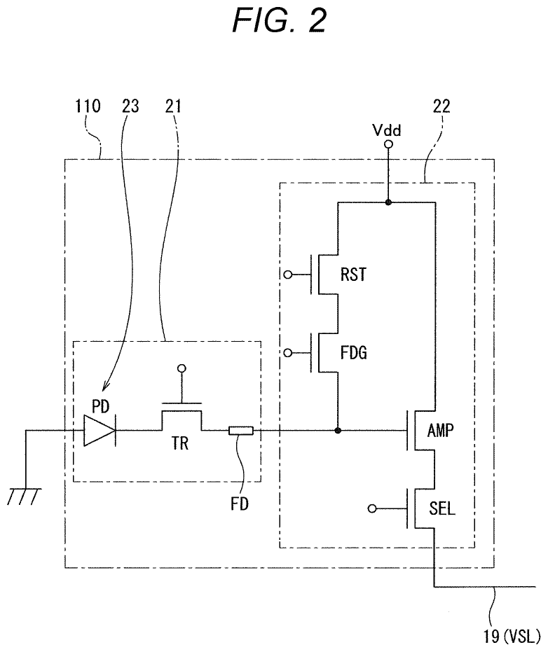

FIG. 2 is a circuit configuration diagram of the pixel 110.

As illustrated in FIG. 2, each of the plurality of pixels 110 includes a photoelectric conversion region 21 and a pixel circuit (readout circuit) 22. The photoelectric conversion region 21 includes a photoelectric converter 23, a transfer transistor TR, and a charge holding region (floating diffusion) FD. The pixel circuit 22 is electrically connected to the charge holding region FD of the photoelectric conversion region 21. The first embodiment has, but is not limited to, a circuit configuration where one pixel circuit 22 is exclusively used by each pixel 110 as an example, and a circuit configuration where one pixel circuit 22 is shared by a plurality of pixels 110 may be employed. For example, a circuit configuration where one pixel circuit 22 is shared by four pixels 110 (one pixel block) arranged in a two-by-two layout, that is, two pixels 110 are arranged in the horizontal direction and two pixels 110 are arranged in the vertical direction, may be employed.

The photoelectric converter 23 includes, for example, a p-n junction photodiode (PD) and generates a signal charge according to the amount of received light. The photoelectric converter 23 has a cathode electrically connected to a source region of the transfer transistor TR and an anode electrically connected to a reference potential line (e.g., ground).

The transfer transistor TR transfers the signal charge generated by photoelectric conversion in the photoelectric converter 23 to the charge holding region FD. The transfer transistor TR has the source region electrically connected to the cathode of the photoelectric converter 23 and a drain region electrically connected to the charge holding region FD. In addition, the transfer transistor TR has a gate electrode electrically connected to a transfer transistor drive line among the pixel drive lines 18 (see FIG. 1).

The charge holding region FD temporarily holds (accumulates) the signal charge transferred from the photoelectric converter 23 via the transfer transistor TR.

The pixel circuit 22 reads the signal charge held in the charge holding region FD, converts the read signal charge into a pixel signal, and outputs the pixel signal. In other words, the pixel circuit 22 converts the signal charge generated by photoelectric conversion in the photoelectric conversion element PD into a pixel signal based on the signal charge and outputs the pixel signal. The pixel circuit 22 includes, but is not limited to, an amplification transistor AMP, a selection transistor SEL, a reset transistor RST, and a switching transistor FDG as pixel transistors, for example. Such pixel transistors (AMP, SEL, RST, FDG) and the above-described transfer transistor TR are each include, for example, a MOSFET as a field effect transistor. Alternatively, these transistors may be MISFETs.

Among the pixel transistors included in the pixel circuit 22, the selection transistor SEL, the reset transistor RST, and the switching transistor FDG each function as a switching element, and the amplification transistor AMP functions as an amplification element.

Note that the selection transistor SEL and the switching transistor FDG may be omitted as necessary.

The amplification transistor AMP has a source region electrically connected to a drain region of the selection transistor SEL and a drain region electrically connected to a power supply line Vdd and a drain region of the reset transistor RST. In addition, the amplification transistor AMP has a gate electrode electrically connected to the charge holding region FD and a source region of the switching transistor FDG.

The selection transistor SEL has a source region electrically connected to the vertical signal line 19 (VSL) and the drain region electrically connected to the source region of the amplification transistor AMP. In addition, the selection transistor SEL has a gate electrode electrically connected to a selection transistor drive line among the pixel drive lines 18 (see FIG. 1).

The reset transistor RST has a source region electrically connected to a drain region of the switching transistor FDG and the drain region electrically connected to the power supply line Vdd and the drain region of the amplification transistor AMP. In addition, the reset transistor RST has a gate electrode electrically connected to a reset transistor drive line among the pixel drive lines 18 (see FIG. 1).

The switching transistor FDG has the source region electrically connected to the charge holding region FD and the gate electrode of the amplification transistor AMP and the drain region electrically connected to the power supply line Vdd and the drain region of the amplification transistor AMP. In addition, the switching transistor FDG has a gate electrode electrically connected to a switching transistor drive line among the pixel drive lines 18 (see FIG. 1).

Note that, in a case where the selection transistor SEL is omitted, the amplification transistor AMP has the source region electrically connected to the vertical signal line (VSL) 19. Furthermore, in a case where the switching transistor FDG is omitted, the reset transistor RST has the source region electrically connected to the gate electrode of the amplification transistor AMP and the charge holding region FD.

When turned on, the transfer transistor TR transfers the signal charge generated by the photoelectric converter 23 to the charge holding region FD.

When turned on, the reset transistor RST resets a potential (signal charge) of the charge holding region FD to a potential of the power supply line Vdd. The selection transistor SEL controls output timing of the pixel signal from the pixel circuit 22.

The amplification transistor AMP generates a voltage signal corresponding to the level of the signal charge held in the charge holding region FD as the pixel signal. The amplification transistor AMP functions as a source follower amplifier, and outputs the pixel signal indicating the voltage corresponding to the level of the signal charge generated by the photoelectric converter 23. When the selection transistor SEL is turned on, the amplification transistor AMP amplifies the potential of the charge holding region FD, and outputs a voltage corresponding to the potential to a column signal processing circuit 5 through the vertical signal line (VSL) 19.

The switching transistor FDG controls charge holding by the charge holding region FD, and adjusts a voltage gain according to the potential amplified by the amplification transistors AMP.

### Semiconductor Structure of Light Detection Device

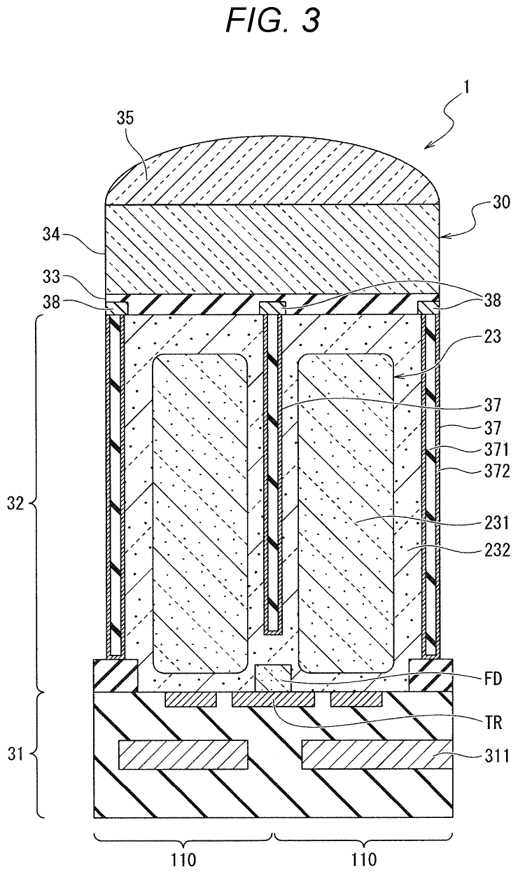

FIG. 3 is a partial longitudinal cross-sectional view illustrating an example of a semiconductor structure of the light detection device 1 according to the first embodiment of the present disclosure. As illustrated in the drawing, a semiconductor structure 30 roughly includes, for example, a wiring layer 31, a semiconductor layer 32, a planarization film 33, a color filter 34, and an on-chip lens 35. Such a semiconductor structure 30 can be formed, for example, by integrally bonding a first silicon substrate including the wiring layer 31 and various logic circuits (not illustrated) and a second silicon substrate including the semiconductor layer 32.

The on-chip lens 35 is an optical lens for efficiently condensing light incident on the light detection device 1 from the outside to form an image on the corresponding plurality of pixels 110 of the semiconductor layer 32. In the present example, the on-chip lenses 35 are arranged one for every four pixels 110 arranged two by two in the horizontal direction (column direction) and the vertical direction (row direction) in plan view. Note that the on-chip lens 35 includes, for example, silicon oxide, silicon nitride, silicon oxynitride, organic SOG, polyimide resin, fluorine resin, or the like.

The color filter 34 is an optical filter that selectively transmits light of a predetermined wavelength of the light condensed by the on-chip lens 35. In the present example, four color filters 24 that selectively transmit wavelengths of red light, green light, blue light, and near-infrared light are used, but the present disclosure is not limited to such a configuration. The color filter 34 corresponding to any color (wavelength) is arranged in each of the pixels 110.

The semiconductor layer 32 is a functional layer in which a pixel circuit group is formed, the pixel circuit group including the photoelectric converter 23 such as a photodiode that is a component of each pixel 110. Each photoelectric converter 23 of the semiconductor layer 32 generates a charge amount corresponding to the intensity of light incident through the on-chip lens 35 and the color filter 34, converts the charge amount into an electric signal, and outputs the electric signal as a pixel signal.

The photoelectric converter 23 includes an n-type region 231 and a p-type region 232. The semiconductor layer 32 is formed on a silicon substrate by a semiconductor manufacturing process. The photoelectric converter 23 and various electronic elements are electrically connected to a predetermined metal wiring in the wiring layer 31.

Furthermore, in the semiconductor layer 32, a pixel isolation section 37 that isolates each pixel 110 can be formed.

The pixel isolation section 37 has, for example, a trench structure formed by etching processing. The pixel isolation section 37 prevents light incident on the pixel 110 from entering the adjacent pixels 110. An insulating film 371 is embedded in the pixel isolation section 37. Furthermore, a fixed charge film 372 that generates a negative fixed charge is formed on an inner wall surface of the pixel isolation section 37. As the fixed charge film 372, it is preferable to use a material capable of enhancing pinning by generating fixed charges when deposited on a substrate such as silicon, and a high refractive index material film or a high dielectric film having a negative charge can be used. This configuration suppresses generation of dark current.

The wiring layer 31 is a layer in which a metal wiring pattern 311 for transmitting power and various drive signals to each pixel 110 in the semiconductor layer 32 and transmitting the pixel signal read from each pixel 110 is formed. The wiring layer 31 can typically include a plurality of layers of the metal wiring patterns 311 stacked together with an interlayer insulating film interposed therebetween. Furthermore, the stacked metal wiring patterns 311 are electrically connected via, for example, vias, as necessary.

A light shielding wall 38 is provided on a back surface side (light incident surface side) of the semiconductor layer 32. The light shielding wall 38 is formed in a grid pattern so as to open the photoelectric converter 23. That is, the light shielding wall 38 is formed at a position corresponding to the pixel isolation section 37. Any material that shields light may be used as the material of the light shielding wall 38, and for example, tungsten (W), aluminum (Al), or copper (Cu) can be used.

### Configuration Example of Pixel Layout

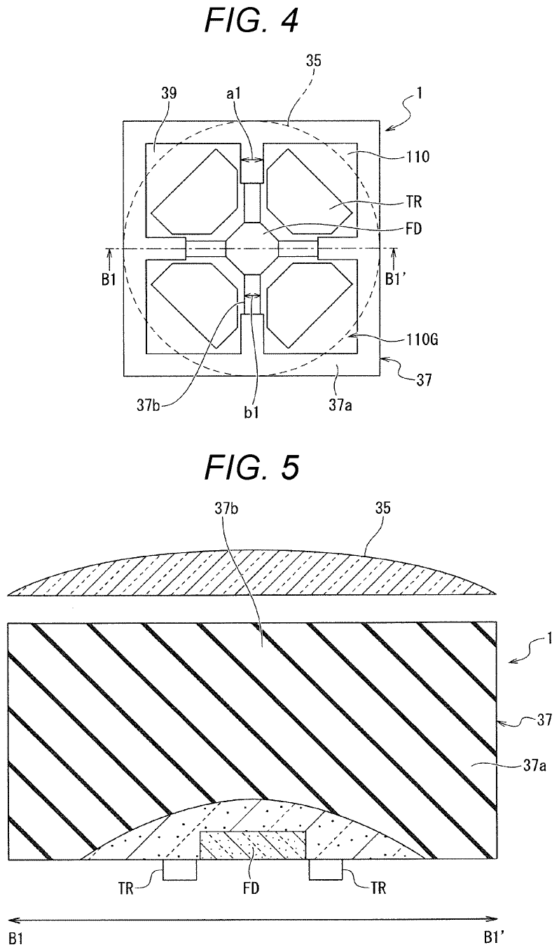

FIG. 4 is a plan view illustrating a configuration example of a pixel layout according to the first embodiment of the present disclosure and an arrangement example of the on-chip lens 35 with respect to the pixel layout. FIG. 5 is a partial longitudinal cross-sectional view illustrating an example of a semiconductor structure in schematic cross section taken along a line B1-B1′ of the pixel group illustrated in FIG. 4.

As illustrated in FIG. 4, the light detection device 1 includes, for example, a pixel group 110G covered with a color filter 34 that transmits green light. The pixel group 110G includes four pixels 110 arranged two by two in the horizontal direction and the vertical direction in plan view. Note that, for example, the pixel group 110G may be covered with a color filter 34 that transmits red light, may be covered with a color filter 34 that transmits blue light, or may be covered with a color filter 34 that transmits light of a different color.

As illustrated in FIG. 4, the on-chip lens 35 is arranged one for every four pixels 110 arranged two by two in the horizontal direction and the vertical direction in plan view. In the configuration example of the pixel layout, the pixels 110 are isolated from each other by the pixel isolation section 37 having a trench isolation structure. For example, the pixel isolation section 37 has a through region 37a having a width al in plan view and a non-through region 37b having a width b1 narrower than the width a1.

As a comparative example of the first embodiment of the present disclosure, the through region 37a and the non-through region 37b are separately formed, resulting in an increase in the number of processes. Furthermore, misalignment at a joint between the through region 37a and the non-through region 37b leads to double processing or makes the pixel isolation section 37 discontinuous.

Therefore, in the first embodiment of the present disclosure, it is possible to make, by forming the non-through region 37b of the pixel isolation section 37 narrower than the through region 37a, the non-through region 37b shallower in a self-alignment manner, thereby allowing simultaneous formation of the through region 37a and the non-through region 37b and a reduction in the number of processes. Furthermore, the junction between the through region 37a and the non-through region 37b is continuous, which eliminates the need of double processing and prevents the pixel isolation section 37 from being discontinuous. Moreover, at a focal position of light condensed by the on-chip lens 35, light scattering due to the non-through region 37b is small.

Furthermore, in the first embodiment of the present disclosure, as illustrated in FIG. 5, the charge holding region FD can be arranged in a region on the opposite side of the light incident surface of the non-through region 37b, so that the silicon region on the opposite side of the light incident surface of the semiconductor layer 32 can be effectively used.

### Effects Produced by First Embodiment

As described above, in the first embodiment, it is possible to make, by forming the non-through region 37b of the pixel isolation section 37 narrower than the through region 37a, the non-through region 37b shallower in a self-alignment manner, thereby allowing simultaneous formation of the through region 37a and the non-through region 37b and a reduction in the number of processes. Furthermore, the junction between the through region 37a and the non-through region 37b is continuous, which eliminates the need of double processing and prevents the pixel isolation section 37 from being discontinuous. Moreover, at a focal position of light condensed by the on-chip lens 35, light scattering due to the non-through region 37b is small.

### Second Embodiment

### Configuration Example of Pixel Layout

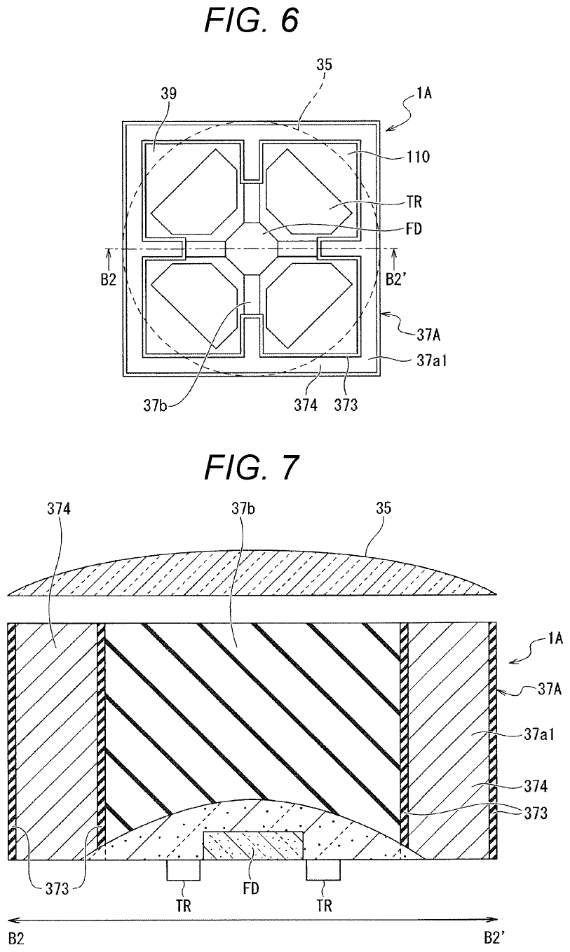

FIG. 6 is a plan view illustrating a configuration example of a pixel layout according to a second embodiment of the present disclosure and an arrangement example of the on-chip lens 35 with respect to the pixel layout. FIG. 7 is a partial longitudinal cross-sectional view illustrating an example of a semiconductor structure in schematic cross section taken along a line B2-B2′ of the pixel group illustrated in FIG. 6. Note that, in FIGS. 6 and 7, the same components as those described above in FIGS. 4 and 5 are denoted by the same reference signs to omit their detailed descriptions.

In a light detection device 1A, the on-chip lens 35 is arranged one for every four pixels 110 arranged two by two in the horizontal direction and the vertical direction in plan view. In the configuration example of the pixel layout, the pixels 110 are isolated from each other by a pixel isolation section 37A having a trench isolation structure. For example, the pixel isolation section 37A has a through region 37a1 and a non-through region 37b narrower than the through region 37a1 in plan view.

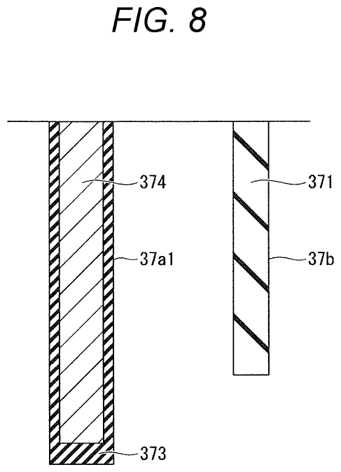

As illustrated in FIG. 8, an insulating film 373 and a light shielding film 374 are embedded in the through region 37a1. The insulating film 371 is embedded in the non-through region 37b. For example, aluminum (Al), tungsten (W), or the like is used for the light shielding film 374. Furthermore, silicon oxide (SiO), titanium oxide (TiO), hafnium oxide (HfO), or the like is used for the insulating films 371 and 373. Silicon oxide (SiO) has a refractive index of 1.45, titanium oxide (TiO) has a refractive index of 2.5, and hafnium oxide (HfO) has a refractive index of 2.1. Silicon (Si) has a refractive index of 3.5. That is, the closer to the refractive index of silicon (Si), the less vignetting (scattering) occurs.

### Effects Produced by Second Embodiment

As described above, according to the second embodiment, it is possible to reduce, by filling the through region 37a1 with the light shielding film 374 including, for example, metal and filling the non-through region 37b with the insulating film 371 including, for example, silicon oxide other than metal, light scattering at the focal position of light condensed by the on-chip lens 35 and impart light-shielding and reflective properties to the through region 37a1.

### Third Embodiment

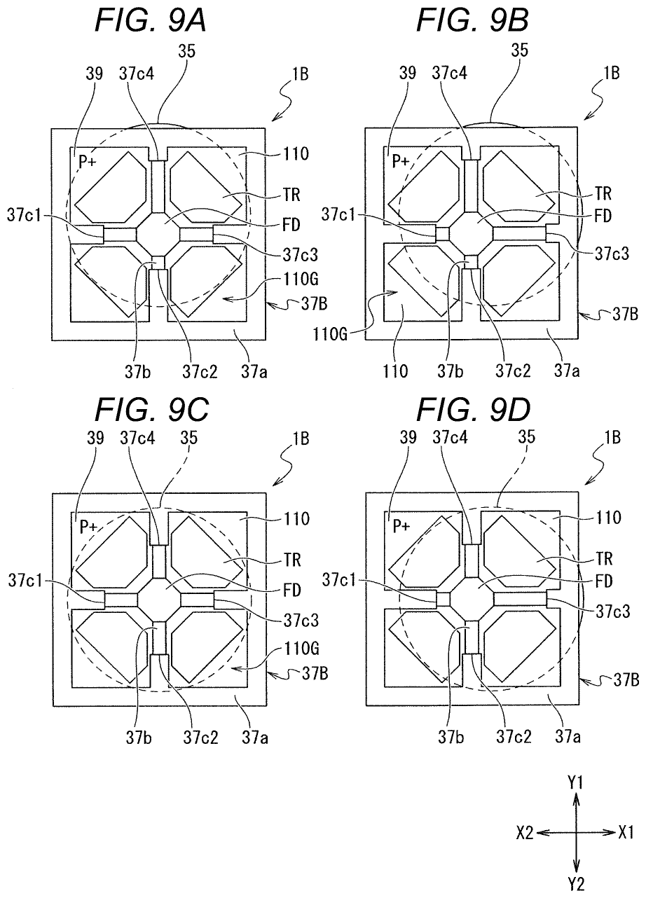

FIG. 9 is a plan view illustrating a configuration example of a pixel layout according to a third embodiment of the present disclosure and an arrangement example of the on-chip lens 35 with respect to the pixel layout. In FIG. 9, the same components as those described above in FIG. 4 are denoted by the same reference signs to omit their detailed descriptions.

In the configuration example of the pixel layout, the pixels 110 are isolated from each other by a pixel isolation section 37B having a trench isolation structure. In FIG. 9, the on-chip lens 35 is arranged according to so-called pupil correction in order to effectively use light at a high image height of the light detection device 1B. That is, as illustrated in FIG. 9(c), the on-chip lens 35 corresponding to the pixel 110 located at the center (zero image height) is arranged to make its optical axis approximately coincident with the center of the pixel 110. Boundaries 37c1, 37c2, 37c3, and 37c4 between the through region 37a and the non-through region 37b are equidistant from the charge holding region FD.

The higher the image height, the more the on-chip lens 35 is shifted from the center of the pixel 110. That is, as illustrated in FIG. 9(a), in a case where the on-chip lens 35 is shifted upward (in the direction indicated by the arrow Y1 in FIG. 9) from the center, the boundaries 37c2 and 37c4 are shifted upward (in the direction indicated by the arrow Y1 in FIG. 9) from the state of FIG. 9(c).

As illustrated in FIG. 9(b), in a case where the on-chip lens 35 is shifted toward the upper right (in the direction indicated by the arrow X1 and the direction indicated by the arrow Y1 in FIG. 9) from the center, the boundaries 37c1 and 37c3 are shifted rightward (in the direction indicated by the arrow X1 in FIG. 9) from the state of FIG. 9(c), and the boundaries 37c2 and 37c4 are shifted upward (in the direction indicated by the arrow Y1 in FIG. 9) from the state of FIG. 9(c).

That is, as illustrated in FIG. 9(d), in a case where the on-chip lens 35 is shifted rightward (in the direction indicated by the arrow X1 in FIG. 9) from the center, the boundaries 37c1 and 37c3 are shifted rightward (in the direction indicated by the arrow X1 in FIG. 9) from the state of FIG. 9(c).

### Effects Produced by Third Embodiment

As described above, according to the third embodiment, it is possible to reduce light scattering by shifting the on-chip lens 35 from the center of the pixel group 110G according to the pupil correction position to shift the boundaries 37c1, 37c2, 37c3, and 37c4 between the through region 37a and the non-through region 37b.

### Fourth Embodiment

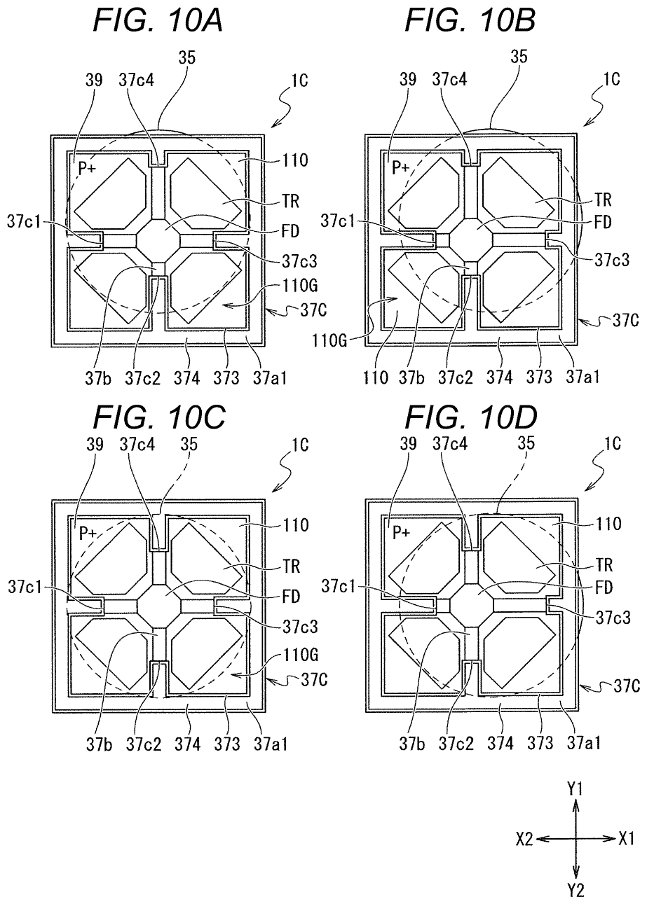

FIG. 10 is a plan view illustrating a configuration example of a pixel layout according to a fourth embodiment of the present disclosure and an arrangement example of the on-chip lens 35 with respect to the pixel layout. In FIG. 10, the same components as those described above in FIG. 6 are denoted by the same reference signs to omit their detailed descriptions.

In a light detection device 1C, the pixels 110 are isolated from each other by a pixel isolation section 37C having a trench isolation structure. For example, the pixel isolation section 37A has a through region 37a1 and a non-through region 37b narrower than the through region 37a1 in plan view. The insulating film 373 and the light shielding film 374 are embedded in the through region 37a1.

That is, as illustrated in FIG. 10(c), the on-chip lens 35 corresponding to the pixel 110 located at the center (zero image height) is arranged to make its optical axis approximately coincident with the center of the pixel 110. Boundaries 37c1, 37c2, 37c3, and 37c4 between the through region 37a1 and the non-through region 37b are equidistant from the charge holding region FD.

The higher the image height, the more the on-chip lens 35 is shifted from the center of the pixel 110. That is, as illustrated in FIG. 10(a), in a case where the on-chip lens 35 is shifted upward (in the direction indicated by the arrow Y1 in FIG. 10) from the center, the boundaries 37c2 and 37c4 are shifted upward (in the direction indicated by the arrow Y1 in FIG. 10) from the state of FIG. 10(c).

As illustrated in FIG. 10(b), in a case where the on-chip lens 35 is shifted toward the upper right (in the direction indicated by the arrow X1 and the direction indicated by the arrow Y1 in FIG. 10) from the center, the boundaries 37c1 and 37c3 are shifted rightward (in the direction indicated by the arrow X1 in FIG. 10) from the state of FIG. 10(c), and the boundaries 37c2 and 37c4 are shifted upward (in the direction indicated by the arrow Y1 in FIG. 10) from the state of FIG. 10(c).

That is, as illustrated in FIG. 10(d), in a case where the on-chip lens 35 is shifted rightward (in the direction indicated by the arrow X1 in FIG. 10) from the center, the boundaries 37c1 and 37c3 are shifted rightward (in the direction indicated by the arrow X1 in FIG. 10) from the state of FIG. 10(c).

### Effects Produced by Fourth Embodiment

As described above, according to the fourth embodiment, it is possible to reduce a component of light reflected off the insulating film 373 and the light shielding film 374 relative to the shift of the on-chip lens 35 in the light detection device 1C due to pupil correction and contribute to improvement of optical characteristics (sensitivity).

### Fifth Embodiment

In a fifth embodiment of the present disclosure, basic processes of the method for manufacturing the light detection device 1 according to the first embodiment will be described.

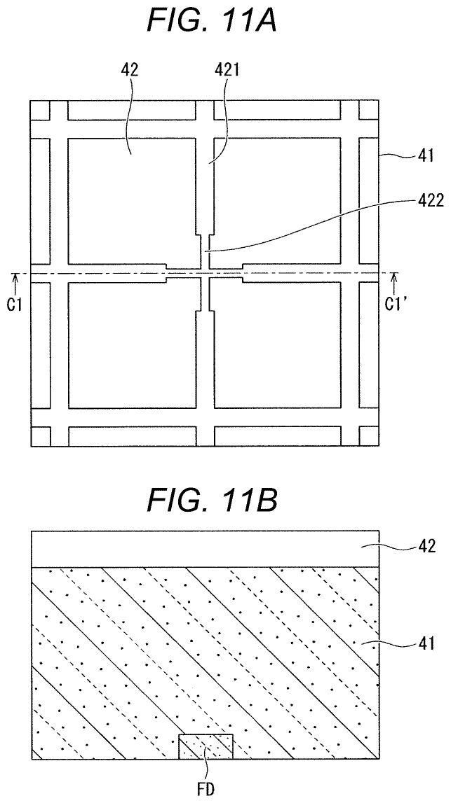

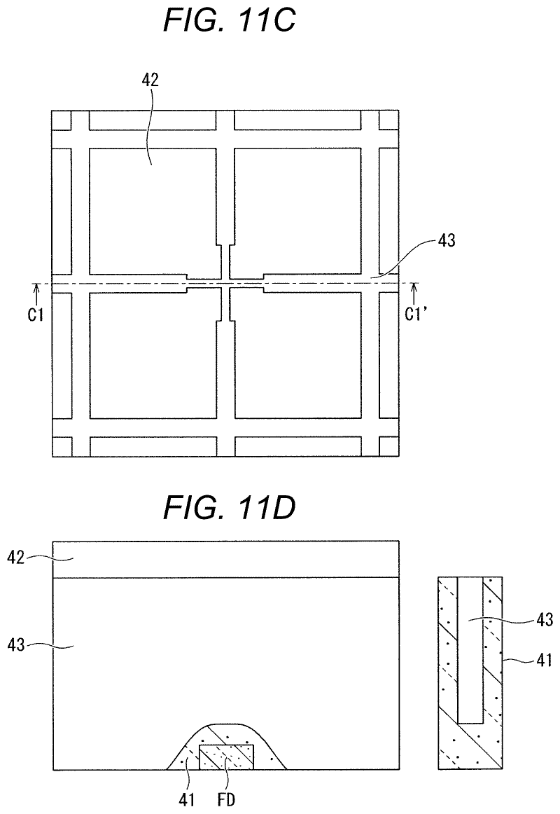

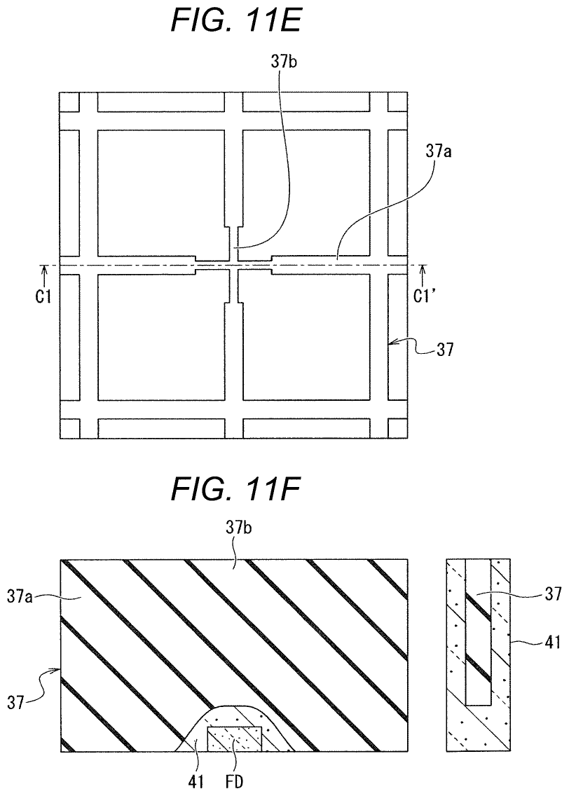

FIG. 11A(1) to 11C(1) are plan views of the light detection device 1 according to the fifth embodiment as viewed from the back surface side. FIG. 11A(2) to 11C(2) are partial cross-sectional views illustrating an example of a semiconductor structure of the light detection device 1 taken along a line C1-C1′. The line C1-C1′ is an imaginary line passing through the through region 37a and the non-through region 37b of the pixel isolation section 37 in plan view.

First, a silicon substrate 41 is prepared, a resist film 42 is formed on the back surface side of the silicon substrate 41, and patterning is performed to make a resist space line width 421 wider in a case where the through region 37a is formed on the resist film 42 by a lithography process and make a resist space line width 422 narrower in a case where the non-through region 37b is formed (FIG. 11A).

Next, the resist space line widths 421 and 422 are opened by dry etching to form an opening 43 (FIG. 11B). In the opening 43, the resist space line width 421 is deeper, and the resist space line width 422 is shallower.

Next, the resist film 42 is removed, and the insulating film 371 is embedded in the opening 43 to form the through region 37a and the non-through region 37b of the pixel isolation section 37 (FIG. 11C). Subsequently, the on-chip lens 35 and the color filter 34 are formed on the back surface side of the silicon substrate 41.

### Effects Produced by Fifth Embodiment

As described above, according to the fifth embodiment, it is possible to make, by forming the non-through region 37b of the pixel isolation section 37 narrower than the through region 37a, the non-through region 37b shallower in a self-alignment manner, thereby allowing simultaneous formation of the through region 37a and the non-through region 37b and a reduction in the number of processes.

### Sixth Embodiment

In a sixth embodiment of the present disclosure, basic processes of the method for manufacturing the light detection device 1A according to the second embodiment will be described.

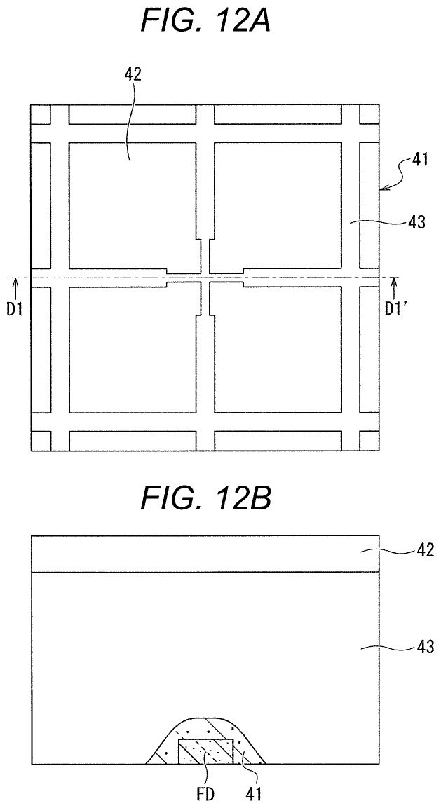

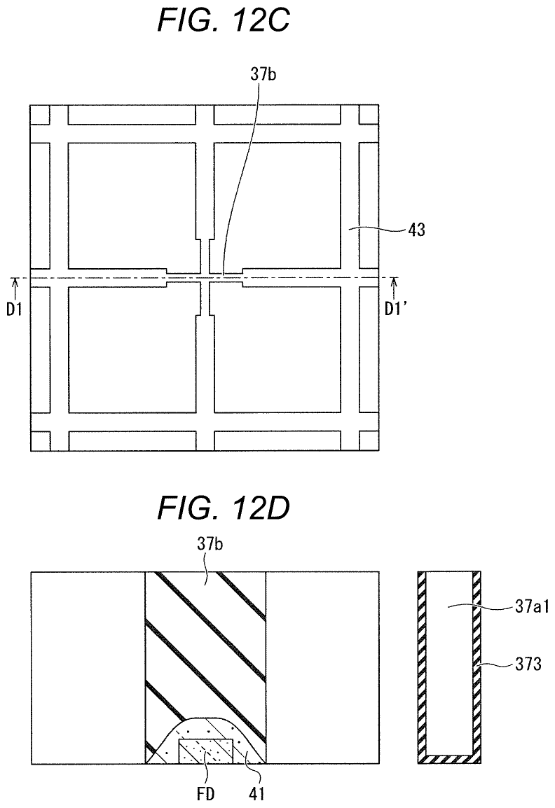

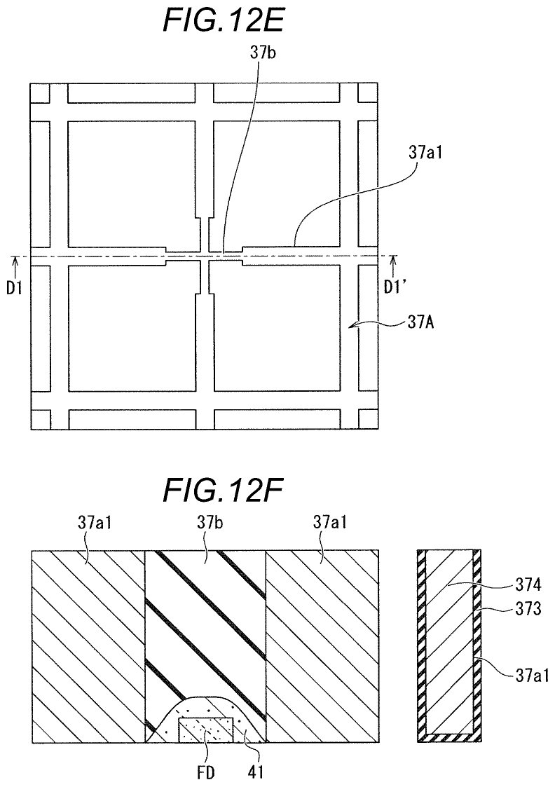

FIG. 12A(1) to 12C(1) are plan views of the light detection device 1A according to the sixth embodiment as viewed from the back surface side. FIG. 12A(2) to 12C(2) are partial cross-sectional views illustrating an example of a semiconductor structure of the light detection device 1A taken along a line D1-D1′. The line D1-D1′ is an imaginary line passing through the through region 37a1 and the non-through region 37b of the pixel isolation section 37A in plan view. Note that, in FIGS. 12A to 12C, the same components as those described above in FIGS. 11A to 11C are denoted by the same reference signs to omit their detailed descriptions.

First, the silicon substrate 41 is prepared, the resist film 42 is formed on the back surface side of the silicon substrate 41, patterning is performed to make the resist space line width wider in a case where the through region 37a1 is formed on the resist film 42 by a lithography process and make the resist space line width narrower in a case where the non-through region 37b is formed, and the resist space line width is opened by dry etching to form the opening 43 (FIG. 12A).

Next, the resist film 42 is removed, and the insulating film 371 is embedded in the opening 43 to form the non-through region 37b of the pixel isolation section 37A (FIG. 12B). Furthermore, the through region 37a1 has a side wall embedded with the insulating film 373 and has a cavity at the center.

Next, the light shielding film 374 is embedded in the center of the trench of the opening 43 to form the through region 37a1 of the pixel isolation section 37A (FIG. 12C). Subsequently, the on-chip lens 35 and the color filter 34 are formed on the back surface side of the silicon substrate 41.

### Effects Produced by Sixth Embodiment

As described above, according to the sixth embodiment, it is possible to form the through region 37a1 and the non-through region 37b simultaneously and reduce the number of processes, in a manner similar to the fifth embodiment.

### Seventh Embodiment

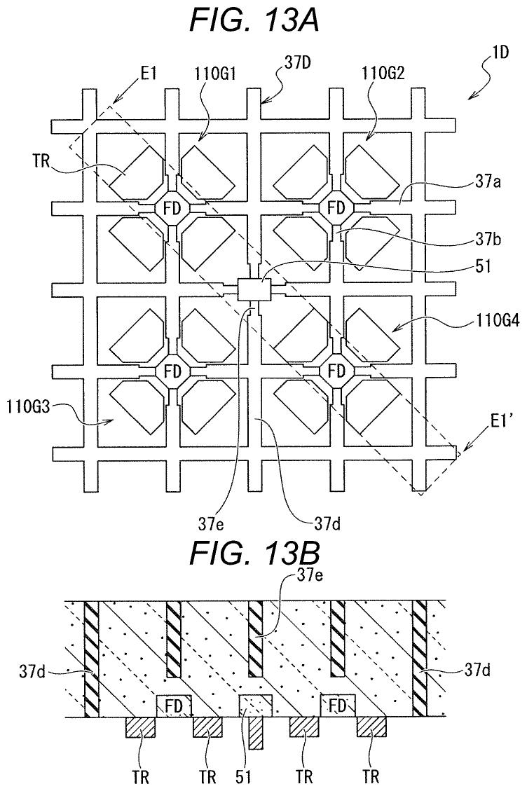

FIG. 13 is a plan view illustrating a configuration example of a pixel layout of a light detection device 1D according to a seventh embodiment of the present disclosure. In FIG. 13, the same components as those described above in FIG. 4 are denoted by the same reference signs to omit their detailed descriptions. FIG. 13(2) is a partial cross-sectional view illustrating an example of a semiconductor structure of the light detection device 1D taken along a line E1-E1′.

As illustrated in FIG. 13(1), the light detection device 1D includes four pixel groups 110G1, 110G2, 110G3, and 110G4. The pixel groups 110G1, 110G2, 110G3, and 110G4 each include four pixels 110 arranged two by two in the horizontal direction and the vertical direction in plan view.

The pixel groups 110G1, 110G2, 110G3, and 110G4 are isolated from each other by a pixel isolation section 37D having a trench isolation structure. For example, the pixel isolation section 37D includes a through region 37d and a non-through region 37e narrower than the through region 37d in plan view.

### Comparative Example of Seventh Embodiment

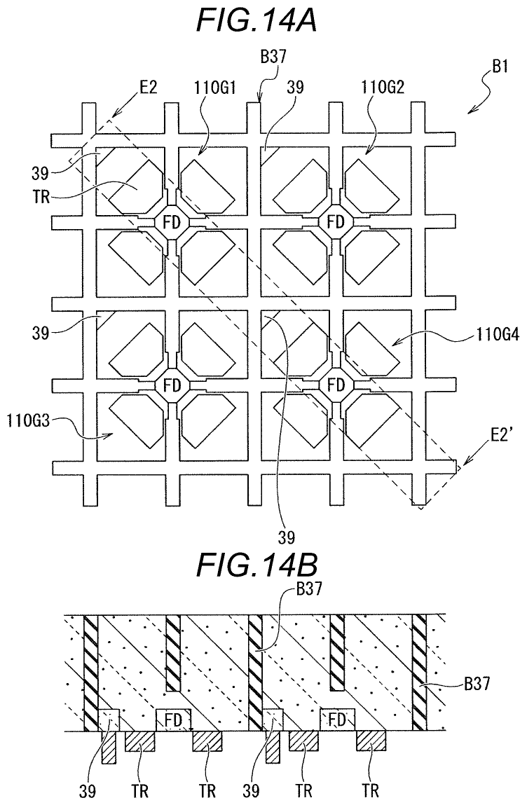

FIG. 14 is a plan view illustrating a configuration example of a pixel layout of a light detection device B1 according to a comparative example of the seventh embodiment. In FIG. 14, the same components as those described above in FIG. 13 are denoted by the same reference signs to omit their detailed descriptions. FIG. 14(2) is a partial cross-sectional view illustrating an example of a semiconductor structure of the light detection device B1 taken along line E2-E2′.

In the light detection device B1, each of the pixel groups 110G1, 110G2, 110G3, and 110G4 includes one well contact 39 used to supply the ground (GND) potential. Meanwhile, in the light detection device B1, the wiring structure of the contact wiring to the pixel transistor becomes complicated.

### Implementation Means According to Seventh Embodiment

Therefore, in the seventh embodiment of the present disclosure, their respective well contacts 39 of the pixel groups 110G1, 110G2, 110G3, and 110G4 opposed diagonally are arranged, in a concentrated manner, in one well contact 51 in the non-through region 37e.

### Effects Produced by Seventh Embodiment

As described above, according to the seventh embodiment, it is possible to reduce, by arranging their respective well contacts 39 of the pixel groups 110G1, 110G2, 110G3, and 110G4 opposed diagonally in one well contact 51 in the non-through region 37e of the pixel isolation section 37D, the number of contact wirings to the pixel transistors and increase the wiring pitch.

### Eighth Embodiment

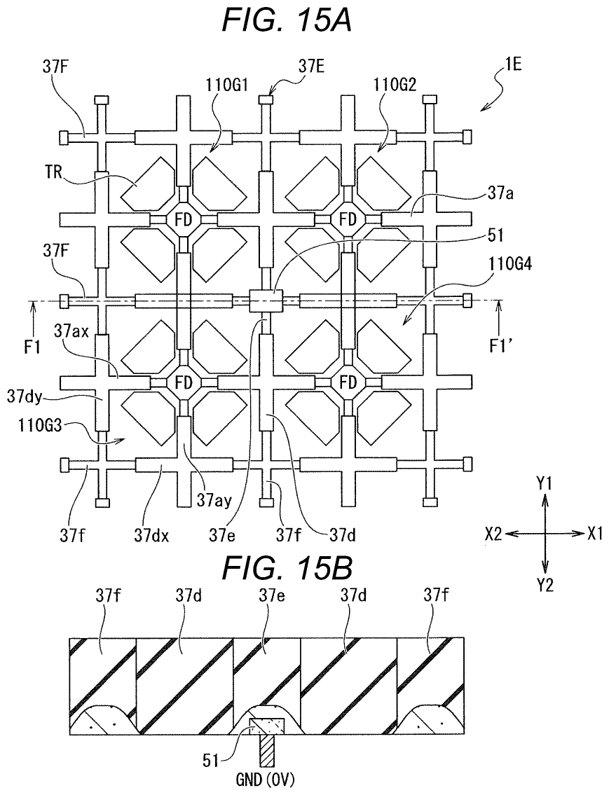

FIG. 15 is a plan view illustrating a configuration example of a pixel layout of a light detection device 1E according to an eighth embodiment of the present disclosure. In FIG. 15, the same components as those described above in FIG. 13 are denoted by the same reference signs to omit their detailed descriptions. FIG. 15(2) is a partial cross-sectional view illustrating an example of a semiconductor structure of the light detection device 1E taken along a line F1-F1′.

As illustrated in FIG. 15(1), the light detection device 1E includes four pixel groups 110G1, 110G2, 110G3, and 110G4. The pixel groups 110G1, 110G2, 110G3, and 110G4 each include four pixels 110 arranged two by two in the horizontal direction and the vertical direction in plan view.

The pixel groups 110G1, 110G2, 110G3, and 110G4 are isolated from each other by a pixel isolation section 37E having a trench isolation structure. For example, the pixel isolation section 37E includes a non-through region 37f where a through region 37dx extending in the row direction (the direction indicated by the arrows X1-X2 in FIG. 15) and a through region 37dy extending in the column direction (the direction indicated by the arrows Y1-Y2 in FIG. 15) intersect in plan view. The non-through region 37f is formed narrower than the through region 37d in plan view.

### Effects Produced by Eighth Embodiment

As described above, according to the eighth embodiment, it is possible to adjust the light collection efficiency of each pixel 110 by arranging the non-through regions 37f symmetrically in the pixel isolation section 37E.

Moreover, in the eighth embodiment, a non-through region may be formed at both an area where the through region 37dx extending in the row direction (the direction indicated by the arrow X1-X2 in FIG. 15) and a through region 37ay extending in the column direction (the direction indicated by the arrow Y1-Y2 in FIG. 15) intersect and at an area where a through region 37ax extending in the row direction (the direction indicated by the arrow X1-X2 in FIG. 15) and the through region 37dy extending in the column direction (the direction indicated by the arrow Y1-Y2 in FIG. 15) intersect. With this configuration, it is possible to further adjust the light collection efficiency of each pixel 110.

### Ninth Embodiment

In a ninth embodiment of the present disclosure, basic processes of the method for manufacturing the light detection device 1E according to the seventh embodiment will be described.

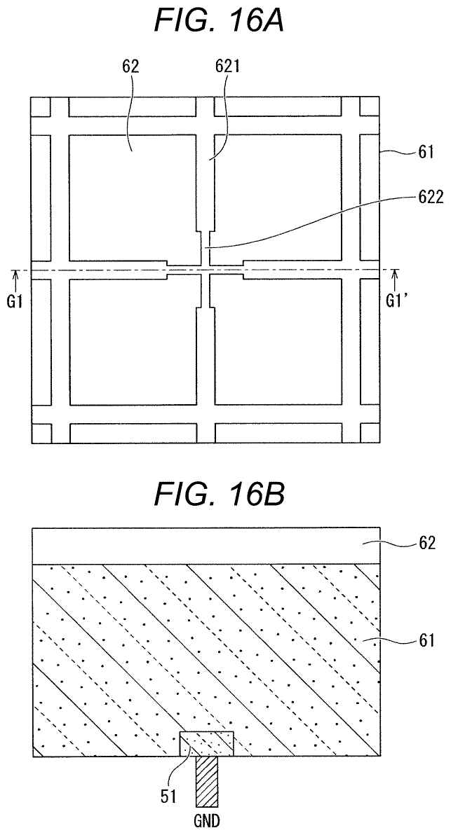

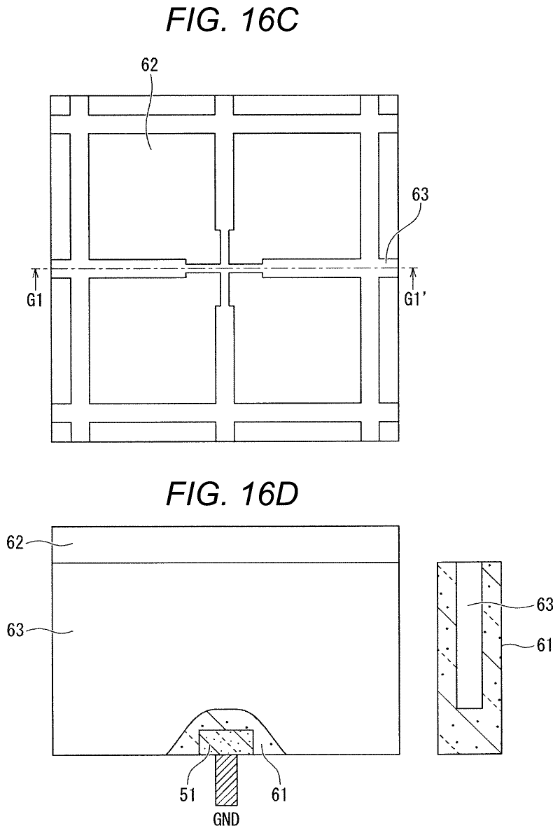

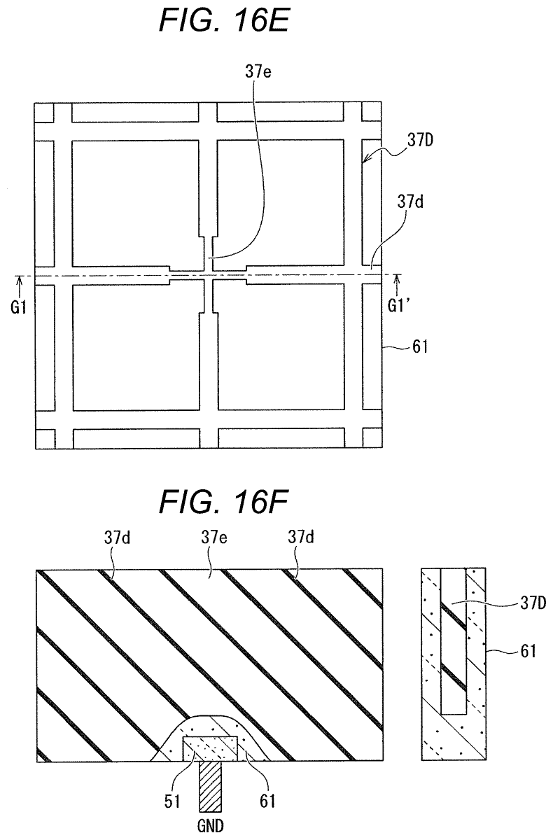

FIG. 16A(1) to 16C(1) are plan views of the light detection device 1E according to the seventh embodiment as viewed from the back surface side. FIG. 16A(2) to 16C(2) are partial cross-sectional views illustrating an example of a semiconductor structure of the light detection device 1E taken along a line G1-G1′. The line G1-G1′ is an imaginary line passing through the through region 37d and the non-through region 37e of the pixel isolation section 37D in plan view.

First, a silicon substrate 61 is prepared, a resist film 62 is formed on the back surface side of the silicon substrate 61, and patterning is performed to make a resist space line width 621 wider in a case where the through region 37d is formed on the resist film 62 by a lithography process and make a resist space line width 622 narrower in a case where the non-through region 37e is formed (FIG. 16A).

Next, the resist space line widths 621 and 622 are opened by dry etching to form an opening 63 (FIG. 16B). In the opening 63, the resist space line width 621 is deeper, and the resist space line width 622 is shallower.

Next, the resist film 62 is removed, and the insulating film 371 is embedded in the opening 63 to form the through region 37d and the non-through region 37e of the pixel isolation section 37D (FIG. 16C). Subsequently, the on-chip lens 35 and the color filter 34 are formed on the back surface side of the silicon substrate 61.

### Effects Produced by Ninth Embodiment

As described above, according to the ninth embodiment, it is possible to make, by forming the non-through region 37e of the pixel isolation section 37D narrower than the through region 37d, the non-through region 37e shallower in a self-alignment manner, thereby allowing simultaneous formation of the through region 37d and the non-through region 37e and a reduction in the number of processes.

### Tenth Embodiment

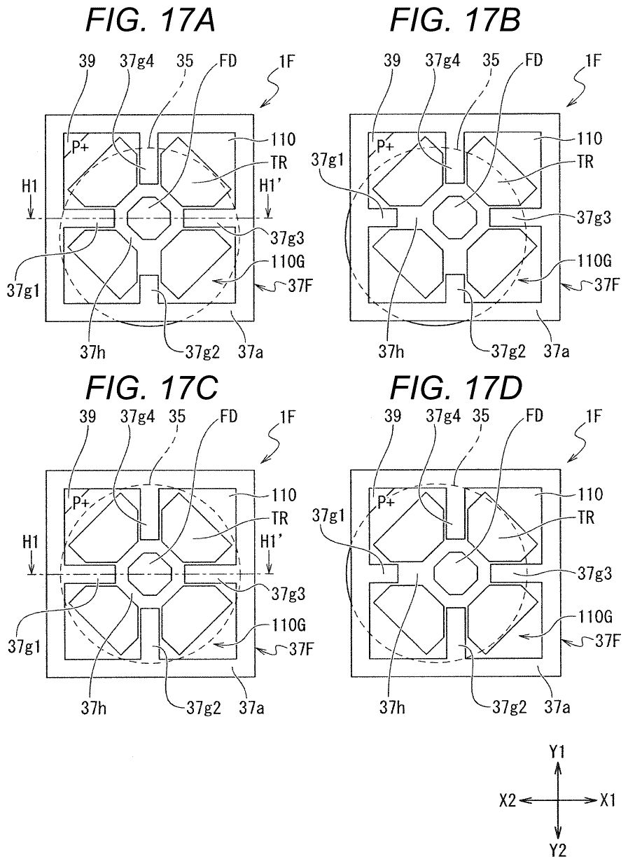

FIG. 17 is a plan view illustrating a configuration example of a pixel layout according to a tenth embodiment of the present disclosure and an arrangement example of the on-chip lens 35 with respect to the pixel layout. In FIG. 17, the same components as those described above in FIG. 4 are denoted by the same reference signs to omit their detailed descriptions.

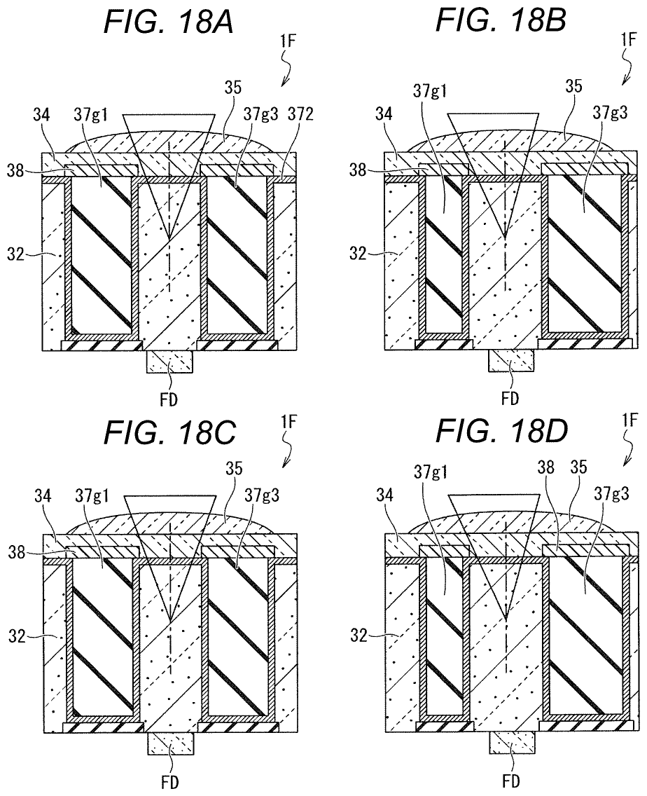

FIG. 18 is a partial cross-sectional view illustrating an example of a semiconductor structure of a light detection device 1F taken along a line H1-H1′ in FIG. 17. In FIG. 18, the same components as those described above in FIG. 3 are denoted by the same reference signs to omit their detailed descriptions.

In the light detection device 1F, the pixels 110 are isolated from each other by a pixel isolation section 37F having a trench isolation structure. The pixel isolation section 37F includes an opening 37h near the charge holding region FD.

In FIG. 17, the on-chip lens 35 is arranged according to so-called pupil correction in order to effectively use light at a high image height of the light detection device 1F. That is, as illustrated in FIG. 17(c), the on-chip lens 35 corresponding to the pixel group 110G located at the center (zero image height) is arranged to make its optical axis approximately coincident with the center of the pixel group 110G. Through regions 37g1, 37g2, 37g3, and 37g4 extend equidistantly from the charge holding region FD.

The higher the image height, the more the on-chip lens 35 is shifted from the center of the pixel group 110G. That is, as illustrated in FIG. 17(a), in a case where the on-chip lens 35 is shifted downward (in the direction indicated by the arrow Y2 in FIG. 17) from the center, the through region 37g4 is extended downward (in the direction indicated by the arrow Y2 in FIG. 17) from the state of FIG. 17(c), and the through region 37g2 is contracted downward (in the direction indicated by the arrow Y2 in FIG. 17) from the state of FIG. 17(c).

That is, as illustrated in FIGS. 17(b) and 18(b), in a case where the on-chip lens 35 is shifted toward the upper right end (in the direction indicated by the arrow X2 and the direction indicated by the arrow Y2 in FIG. 17) from the center, the through region 37g4 is extended downward (in the direction indicated by the arrow Y2 in FIG. 17) from the state of FIG. 17(c), and the through region 37g2 is contracted downward (in the direction indicated by the arrow Y2 in FIG. 17) from the state of FIG. 17(c). Furthermore, the through region 37g3 is extended leftward (the direction indicated by the arrow X2 in FIG. 17) from the state in FIG. 17(c), and the through region 37g1 is contracted leftward (the direction indicated by the arrow X2 in FIG. 17) from the state in FIG. 17(c).

That is, as illustrated in FIG. 17(d) and 18(d), in a case where the on-chip lens 35 is shifted leftward (in the direction indicated by the arrow X2 in FIG. 17) from the center, the through region 37g3 is extended leftward (in the direction indicated by the arrow X2 in FIG. 17) from the state of FIG. 17(c), and the through region 37g1 is contracted leftward (in the direction indicated by the arrow X2 in FIG. 17) from the state of FIG. 17(c).

### Effects Produced by Tenth Embodiment

As described above, according to the tenth embodiment, with a higher image height, the position of the on-chip lens 35 is shifted according to the emission direction of the principal ray, and the formation position of the opening 37h of the pixel isolation section 37F is also shifted, so that it is possible to use the principal ray obliquely incident at a high image height, eliminate the need of the non-through trench at the focal position in the on-chip lens 35, and contribute to improvement of optical characteristics. Furthermore, the number of processes can be reduced.

Furthermore, according to the tenth embodiment, it is possible to reduce a component of light reflected off or scattered by the light shielding wall 38 and the embedded film relative to the shift of the on-chip lens 35 in the light detection device 1F (chip) due to pupil correction and contribute to improvement of optical characteristics.

### Eleventh Embodiment

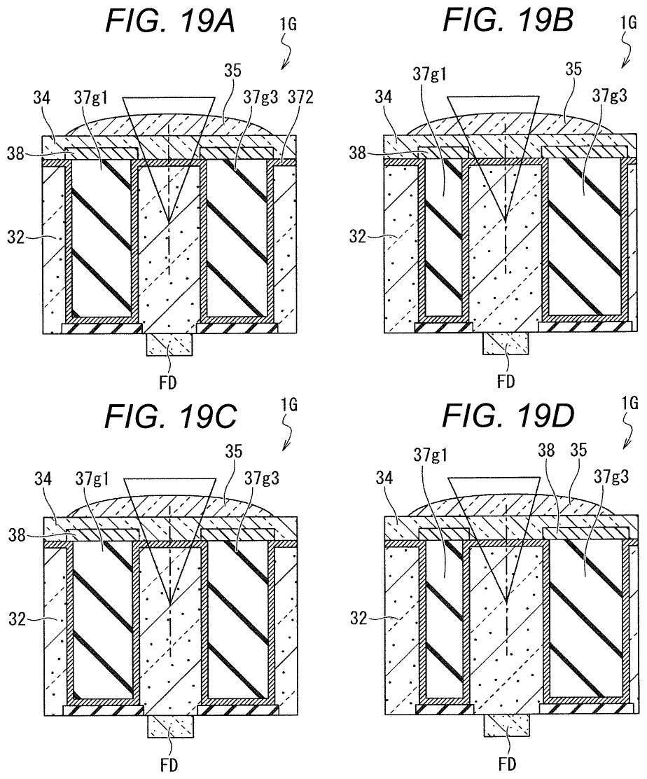

FIG. 19 is a cross-sectional view illustrating a configuration example of a pixel layout according to an eleventh embodiment of the present disclosure and an arrangement example of the on-chip lens 35 with respect to the pixel layout. In FIG. 19, the same components as those described above in FIG. 18 are denoted by the same reference signs to omit their detailed descriptions.

That is, as illustrated in FIG. 19(c), the on-chip lens 35 corresponding to the pixel group 110G located at the center (zero image height) is arranged to make its optical axis approximately coincident with the center of the pixel group 110G. Through regions 37g1 and 37g3 extend equidistantly from the charge holding region FD.

As illustrated in FIG. 19(a), in a case where the on-chip lens 35 is shifted downward (in the direction indicated by the arrow Y2 in FIG. 17) from the center, the through region 37g4 is extended downward (in the direction indicated by the arrow Y2 in FIG. 17) from the state of FIG. 19(c), and the through region 37g2 is contracted downward (in the direction indicated by the arrow Y2 in FIG. 17) from the state of FIG. 19(c).

That is, as illustrated in FIG. 19(b), in a case where the on-chip lens 35 is shifted toward the upper right end (in the direction indicated by the arrow X2 and the direction indicated by the arrow Y2 in FIG. 17) from the center, the through region 37g3 is extended leftward (in the direction indicated by the arrow X2 in FIG. 19) from the state of FIG. 19(c), and the through region 37g1 is contracted leftward (in the direction indicated by the arrow X2 in FIG. 19) from the state of FIG. 19(c). Moreover, the formation position of the charge holding region FD is also shifted leftward (in the direction indicated by the arrow X2 in FIG. 19) from the state of FIG. 19(c).

As illustrated in FIG. 19(d), in a case where the on-chip lens 35 is shifted leftward (in the direction indicated by the arrow X2 in FIG. 19) from the center, the through region 37g3 is extended leftward (in the direction indicated by the arrow X2 in FIG. 19) from the state of FIG. 19(c), and the through region 37g1 is contracted leftward (in the direction indicated by the arrow X2 in FIG. 19) from the state of FIG. 19(c). Moreover, the formation position of the charge holding region FD is also shifted leftward (in the direction indicated by the arrow X2 in FIG. 19) from the state of FIG. 19(c).

### Effects produced by Eleventh Embodiment

As described above, according to the eleventh embodiment, it is possible to reduce, by shifting the formation position of the charge holding region FD according to the pupil correction position, the influence of the strong electric field from the pixel isolation section 37F.

### Twelfth Embodiment

In a twelfth embodiment of the present disclosure, basic processes of the method for manufacturing the light detection device 1F according to the tenth embodiment will be described.

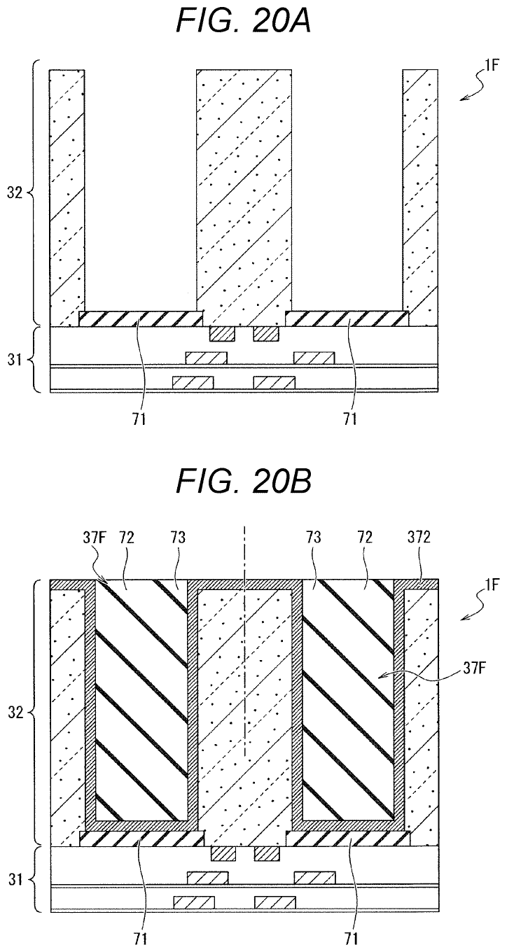

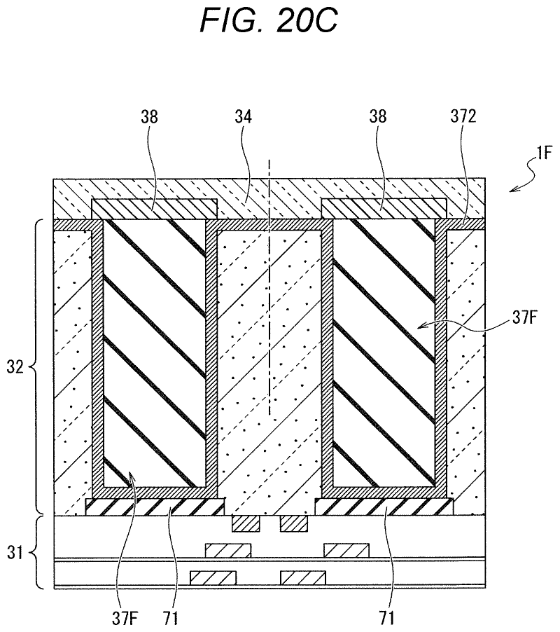

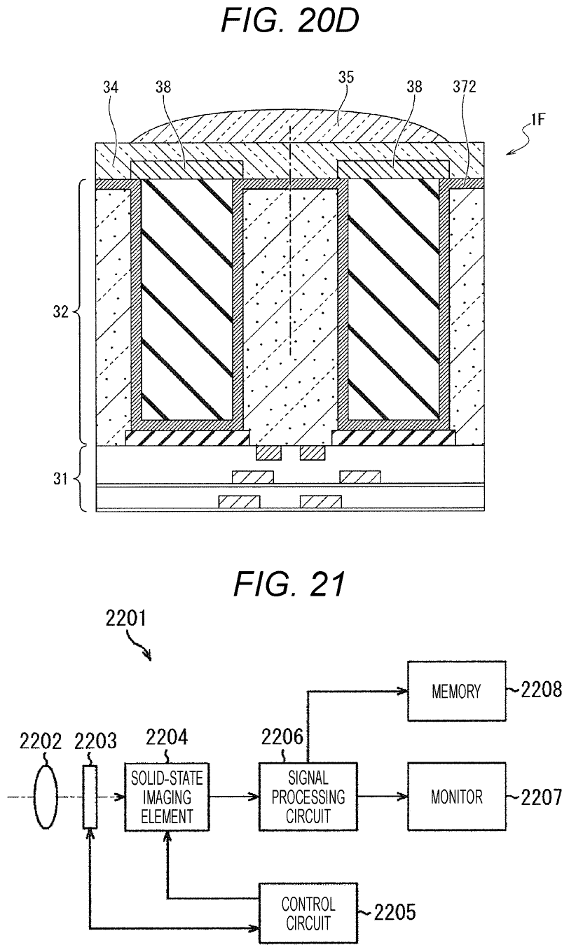

FIGS. 20A to 20D are partial cross-sectional views illustrating an example of a semiconductor structure of the light detection device 1F according to the twelfth embodiment. In FIGS. 20A to 20D, the same components as those described above in FIGS. 3 and 18 are denoted by the same reference signs to omit their detailed descriptions.

The semiconductor layer 32 with the wiring layer 31 bonded to its front surface is prepared, and the semiconductor layer 32 is penetrated from the back surface side to an STI section 71 (FIG. 20A). Note that, as a modification, processing and planarization from the surface process are also possible.

Next, the insulating film 73 such as silicon oxide (SiO) is embedded in a through opening 72 to form the pixel isolation section 37F, and the fixed charge film 372 that generates a negative fixed charge is formed on the inner wall surface of the pixel isolation section 37F (FIG. 20B).

Next, the light shielding wall 38 is formed on the back surface side of the pixel isolation section 37F, and the color filter 34 is further formed (FIG. 20C). As the light shielding wall 38, a high-reflective metal film or a low-refractive index material film can be used. Subsequently, the on-chip lens 35 is formed on the back surface side of the color filter 34 (FIG. 20D).

### Other Embodiments

The present technology has been described as above according to the first to twelfth embodiments, but it should not be understood that the description and drawings forming a part of this disclosure limit the present technology. It will be apparent to those skilled in the art that various alternative embodiments, examples, and operation techniques can be included in the present technology when understanding the spirit of the technical content disclosed in the first to twelfth embodiments described above. Furthermore, the configurations disclosed in the first to twelfth embodiments can be appropriately combined within a range in which no contradiction occurs. For example, configurations disclosed in a plurality of different embodiments may be combined, or configurations disclosed in a plurality of different modifications of the same embodiment may be combined.

### Application Example to Electronic Apparatus

The light detection device described above can be applied to various electronic apparatuses such as an imaging device such as a digital still camera or a digital video camera, a mobile phone with an imaging function, or another type of apparatus with an imaging function.

FIG. 21 is a block diagram illustrating a configuration example of an imaging device as an electronic apparatus to which the present technology is applied.

An imaging device 2201 illustrated in FIG. 21 includes an optical system 2202, a shutter device 2203, a solid-state imaging element 2204 as a light detection device, a control circuit 2205, a signal processing circuit 2206, a monitor 2207, and two memories 2208, and can capture a still image and a moving image.

The optical system 2202 includes one or a plurality of lenses, and guides light from a subject (incident light) to the solid-state imaging element 2204 to form an image on a light receiving surface of the solid-state imaging element 2204.

The shutter device 2203 is arranged between the optical system 2202 and the solid-state imaging element 2204 and controls a light irradiation period and a light shielding period for the solid-state imaging element 2204 under the control of the control circuit 2205.

The solid-state imaging element 2204 includes a package including the solid-state imaging element described above. The solid-state imaging element 2204 accumulates a signal charge for a certain period according to light formed as an image on the light receiving surface via the optical system 2202 and the shutter device 2203. The signal charge accumulated in the solid-state imaging element 2204 is transferred according to a drive signal (timing signal) supplied from the control circuit 2205.

The control circuit 2205 outputs the drive signal to control a transfer operation of the solid-state imaging element 2204 and a shutter operation of the shutter device 2203, to drive the solid-state imaging element 2204 and the shutter device 2203.

The signal processing circuit 2206 performs various types of signal processing on the signal charge output from the solid-state imaging element 2204. An image (image data) obtained by the signal processing performed by the signal processing circuit 2206 is supplied to the monitor 2207 to be displayed or supplied to the memory 2208 to be stored (recorded).

Also in the imaging device 2201 configured as described above, the light detection device 1 can be applied instead of the solid-state imaging element 2204 described above.

### Application Example to Mobile Structure

The technology according to the present disclosure (the present technology) can be applied to various products. For example, the technology according to the present disclosure may be embodied in the form of a device to be mounted on a mobile structure of any kind, such as an automobile, an electric vehicle, a hybrid electric vehicle, a motorcycle, a bicycle, a personal mobility, an airplane, a drone, a vessel, or a robot.

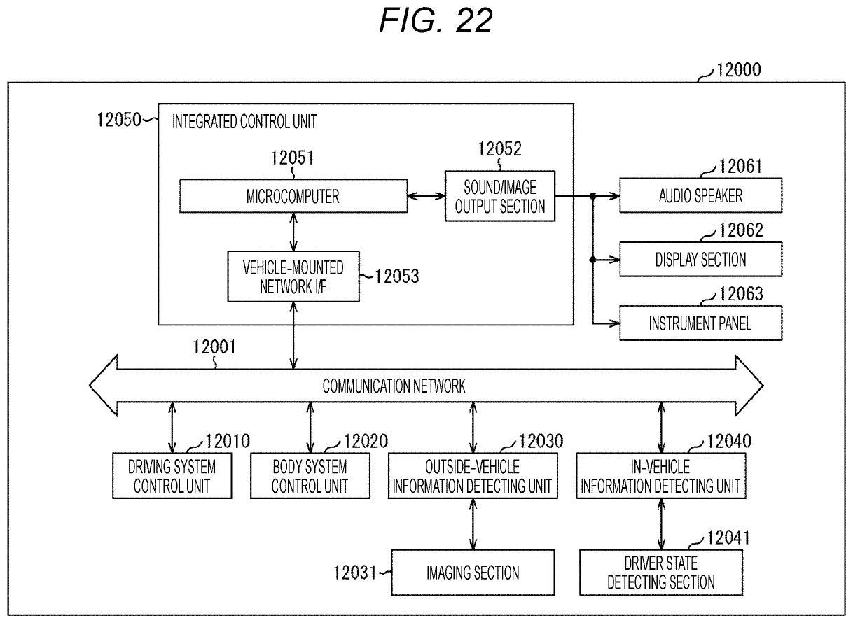

FIG. 22 is a block diagram illustrating a schematic configuration example of a vehicle control system which is an example of a mobile structure control system to which the technology according to the present disclosure can be applied.

The vehicle control system 12000 includes a plurality of electronic control units connected to each other via a communication network 12001. In the example illustrated in FIG. 22, the vehicle control system 12000 includes a driving system control unit 12010, a body system control unit 12020, an outside-vehicle information detecting unit 12030, an in-vehicle information detecting unit 12040, and an integrated control unit 12050. Further, a microcomputer 12051, a sound/image output section 12052, and a vehicle-mounted network interface (I/F) 12053 are illustrated as functional components of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Furthermore, the microcomputer 12051 can output a control command to the body system control unit 12020, on the basis of the information regarding the outside of the vehicle acquired by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example in FIG. 22, an audio speaker 12061, a display section 12062, and an instrument panel 12063 are illustrated as output devices. The display section 12062 may, for example, include at least one of an on-board display and a head-up display.

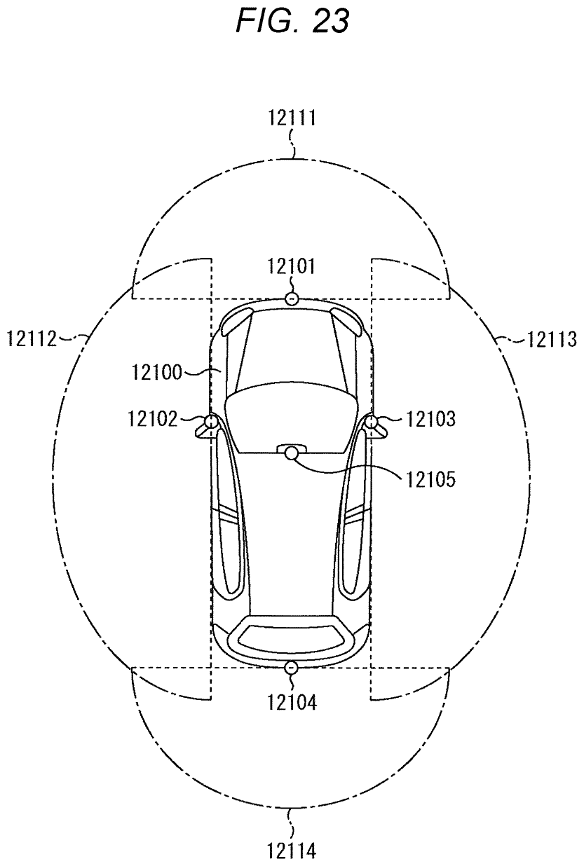

FIG. 23 is a diagram illustrating an example of an installation position of the imaging section 12031.

In FIG. 23, a vehicle 12100 has imaging sections 12101, 12102, 12103, 12104, and 12105 as the imaging section 12031.

The imaging sections 12101, 12102, 12103, 12104, and 12105 are provided at positions such as a front nose, a sideview mirror, a rear bumper, a back door, and an upper portion of a windshield in the interior of the vehicle 12100, for example. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly images of the sides of the vehicle 12100. The imaging section 12104 provided to the rear bumper or the back door obtains mainly an image of the rear of the vehicle 12100. Forward images to be obtained by the imaging sections 12101 and 12105 are used mainly to detect a preceding vehicle, a pedestrian, an obstacle, a traffic signal, a traffic sign, a lane, or the like.

Note that FIG. 23 illustrates an example of imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

Note that the present disclosure may also have the following configurations.
(1)

A light detection device including:
a semiconductor substrate in which a plurality of pixels capable of generating an electric signal according to light incident from an outside is arranged in a matrix;
a pixel isolation section provided in the semiconductor substrate to isolate the pixels adjacent to each other; and
an on-chip lens arranged on a light incident surface side of the semiconductor substrate for each pixel group including at least two of the plurality of pixels, the on-chip lens being configured to condense the light from the outside onto the pixel group, in which
the pixel isolation section includes
an intra-pixel group isolation section arranged between the pixels adjacent to each other of the pixel group and including a first recessed region extending in a thickness direction of the semiconductor substrate and a second recessed region located at a focal position of the light condensed by the on-chip lens, the second recessed region being different from the first recessed region, and
in the intra-pixel group isolation section, the second recessed region is formed narrower than the first recessed region in plan view.
(2)

The light detection device according to the above (1), in which the semiconductor substrate includes an element arranged in a region on an opposite side of the light incident surface of the second recessed region.
(3)

The light detection device according to the above (1), in which
the on-chip lens is arranged to be shifted in a predetermined direction from a center of the pixel group according to a pupil correction position, and
the intra-pixel group isolation section shifts a position of a boundary between the first recessed region and the second recessed region according to the pupil correction position.
(4)

The light detection device according to the above (1), in which the first recessed region of the intra-pixel group isolation section is filled with a first film, and the second recessed region of the intra-pixel group isolation section is filled with a second film different from the first film.
(5)

The light detection device according to the above (4), in which
the first film includes a metal film, and
the second film includes a film other than the metal film.
(6)

The light detection device according to the above (1), in which
each of a plurality of pixel groups includes one well contact used to supply a ground potential,
the pixel isolation section includes a pixel group isolation section arranged between the pixel groups adjacent to each other and including a third recessed region extending in the thickness direction of the semiconductor substrate, and
the pixel group isolation section includes a fourth recessed region in which the respective well contacts of pixel groups opposed diagonally among the plurality of pixel groups are intensively arranged, and the fourth recessed region is formed narrower than the third recessed region in plan view.
(7)

The light detection device according to the above (6), in which the pixel group isolation section includes a fifth recessed region in which the third recessed region extending in a row direction and the third recessed region extending in a column direction intersect, and the fifth recessed region is formed narrower than the third recessed region in plan view.
(8)

The light detection device according to the above (6), in which the pixel group isolation section includes a sixth recessed region intersecting the intra-pixel group isolation section, and the sixth recessed region is formed narrower than the third recessed region in plan view.
(9)

A method for manufacturing a light detection device, the light detection device including:
a semiconductor substrate in which a plurality of pixels capable of generating an electric signal according to light incident from an outside is arranged in a matrix;
a pixel isolation section provided in the semiconductor substrate to isolate the pixels adjacent to each other;
and an on-chip lens arranged on a light incident surface side of the semiconductor substrate for each pixel group including at least two of the plurality of pixels, the on-chip lens being configured to condense the light from the outside onto the pixel group, the method including:
a first process of forming an intra-pixel group isolation section between the pixels adjacent to each other of the pixel group and including a first recessed region extending in a thickness direction of the semiconductor substrate and a second recessed region located at a focal position of the light condensed by the on-chip lens, the second recessed region being different from the first recessed region, in which
in the first process, the second recessed region is formed narrower than the first recessed region in plan view.
(10)

The method for manufacturing a light detection device according to the above (9), further including:
a second process of filling the second recessed region with a first film; and
a third process of filling the first recessed region with a second film different from the first film.
(11)

The method for manufacturing a light detection device according to the above (10), in which
the second film includes a metal film, and
the first film includes a film other than the metal film.
(12)

A light detection device including:
a semiconductor substrate in which a plurality of pixels capable of generating an electric signal according to light incident from an outside is arranged in a matrix;

a pixel isolation section provided in the semiconductor substrate to isolate the pixels adjacent to each other; and
an on-chip lens arranged on a light incident surface side of the semiconductor substrate for each pixel group including at least two of the plurality of pixels, the on-chip lens being configured to condense the light from the outside onto the pixel group, in which
the pixel isolation section includes
an intra-pixel group isolation section arranged between the pixels of the same color adjacent to each other and having an opening at least in a part of a focal position of the light condensed by the on-chip lens,
the on-chip lens is arranged to be shifted in a predetermined direction from a center of the pixel group according to a pupil correction position, and
a formation position of the opening of the intra-pixel group isolation section is shifted according to the pupil correction position.
(13)

The light detection device according to the above (12), in which the intra-pixel group isolation section changes an extension distance in a row direction or a column direction of the intra-pixel group isolation section according to the pupil correction position.
(14)

The light detection device according to the above (12), further including
a charge accumulation section formed in the semiconductor substrate and configured to store a charge generated by each of the pixels, in which
a formation position of the charge accumulation section is shifted according to the pupil correction position.
(15)

An electronic apparatus including a light detection device, the light detection device including:
a semiconductor substrate in which a plurality of pixels capable of generating an electric signal according to light incident from an outside is arranged in a matrix;
a pixel isolation section provided in the semiconductor substrate to isolate the pixels adjacent to each other; and
an on-chip lens arranged on a light incident surface side of the semiconductor substrate for each pixel group including at least two of the plurality of pixels, the on-chip lens being configured to condense the light from the outside onto the pixel group, in which
the pixel isolation section includes
an intra-pixel group isolation section arranged between the pixels adjacent to each other of the pixel group and including a first recessed region extending in a thickness direction of the semiconductor substrate and a second recessed region located at a focal position of the light condensed by the on-chip lens, the second recessed region being different from the first recessed region, and
in the intra-pixel group isolation section, the second recessed region is formed narrower than the first recessed region in plan view.
(16)

An electronic apparatus including a light detection device, the light detection device including:
a semiconductor substrate in which a plurality of pixels capable of generating an electric signal according to light incident from an outside is arranged in a matrix;
a pixel isolation section provided in the semiconductor substrate to isolate the pixels adjacent to each other; and
an on-chip lens arranged on a light incident surface side of the semiconductor substrate for each pixel group including at least two of the plurality of pixels, the on-chip lens being configured to condense the light from the outside onto the pixel group, in which
the pixel isolation section includes
an intra-pixel group isolation section arranged between the pixels adjacent to each other of the pixel group and having an opening at least in a part of a focal position of the light condensed by the on-chip lens,
the on-chip lens is arranged to be shifted in a predetermined direction from a center of the pixel group according to a pupil correction position, and
a formation position of the opening of the intra-pixel group isolation section is shifted according to the pupil correction position.

### REFERENCE SIGNS LIST

1, 1A, 1B, 1C, 1D, 1E, 1F Light detection device
5 Column signal processing circuit
11 Pixel array unit
12 Vertical drive unit
13 Column processing unit
14 Horizontal drive unit
15 System control unit
16 Signal processing unit
17 Data storage unit
18 Pixel drive line
19 Vertical signal line
21 Photoelectric conversion region
22 Pixel circuit (readout circuit)
23 Photoelectric converter
24 Color filter
30 Semiconductor structure
31 Wiring layer
32 Semiconductor layer
33 Planarization film
34 Color filter
35 On-chip lens
37, 37A, 37B, 37C, 37D, 37E, 37F Pixel isolation section
37a, 37a1, 37ax, 37ay, 37d, 37dx, 37dy, 37g1, 37g2, 37g3, 37g4 Through region
37b, 37e, 37f Non-through region
37c1, 37c2, 37c3, 37c4 Boundary
37h Opening
38 Light shielding wall
39 Well contact
41, 61 Silicon substrate
42, 62 Resist film
43, 63 Opening
51 Well contact
71, 72 STI section
73 Insulating film
110 Pixel
110G, 110G1, 110G2, 110G3, 110G4 Pixel group
231 n-type region
232 p-type region
311 Metal wiring pattern
371 Insulating film
372 Fixed charge film
373 Insulating film
374 Light shielding film
421, 422, 621, 622 Resist space line width
2201 Imaging device
2202 Optical system
2203 Shutter device
2204 Solid-state imaging element
2205 Control circuit
2206 Signal processing circuit
2207 Monitor
2208 Memory
12000 Vehicle control system
12001 Communication network
12010 Driving system control unit
12020 Body system control unit
12030 Outside-vehicle information detecting unit
12031 Imaging section
12040 In-vehicle information detecting unit
12041 Driver state detecting section
12050 Integrated control unit
12051 Microcomputer
12052 Sound/image output section
12061 Audio speaker
12062 Display section
12063 Instrument panel
12100 Vehicle
12101 to 12105 Imaging section
12111 to 12114 Imaging range

What is claimed is:

1. A light detection device comprising:
a semiconductor substrate in which a plurality of pixels capable of generating an electric signal according to light incident from an outside is arranged in a matrix;
a pixel isolation section provided in the semiconductor substrate to isolate the pixels adjacent to each other; and
an on-chip lens arranged on a light incident surface side of the semiconductor substrate for each pixel group including at least two of the plurality of pixels, the on-chip lens being configured to condense the light from the outside onto the pixel group, wherein
the pixel isolation section includes
an intra-pixel group isolation section arranged between the pixels adjacent to each other of the pixel group and including a first recessed region extending in a thickness direction of the semiconductor substrate and a second recessed region located at a focal position of the light condensed by the on-chip lens, the second recessed region being different from the first recessed region, and
in the intra-pixel group isolation section, the second recessed region is formed narrower than the first recessed region in plan view.

2. The light detection device according to claim 1, wherein the semiconductor substrate includes an element arranged in a region on an opposite side of the light incident surface of the second recessed region.

3. The light detection device according to claim 1, wherein
the on-chip lens is arranged to be shifted in a predetermined direction from a center of the pixel group according to a pupil correction position, and
the intra-pixel group isolation section shifts a position of a boundary between the first recessed region and the second recessed region according to the pupil correction position.

4. The light detection device according to claim 1, wherein the first recessed region of the intra-pixel group isolation section is filled with a first film, and the second recessed region of the intra-pixel group isolation section is filled with a second film different from the first film.

5. The light detection device according to claim 4, wherein
the first film includes a metal film, and
the second film includes a film other than the metal film.

6. The light detection device according to claim 1, wherein
each of a plurality of pixel groups includes one well contact used to supply a ground potential,
the pixel isolation section includes a pixel group isolation section arranged between the pixel groups adjacent to each other and including a third recessed region extending in the thickness direction of the semiconductor substrate, and
the pixel group isolation section includes a fourth recessed region in which the respective well contacts of pixel groups opposed diagonally among the plurality of pixel groups are intensively arranged, and the fourth recessed region is formed narrower than the third recessed region in plan view.

7. The light detection device according to claim 6, wherein the pixel group isolation section includes a fifth recessed region in which the third recessed region extending in a row direction and the third recessed region extending in a column direction intersect, and the fifth recessed region is formed narrower than the third recessed region in plan view.

8. The light detection device according to claim 6, wherein the pixel group isolation section includes a sixth recessed region intersecting the intra-pixel group isolation section, and the sixth recessed region is formed narrower than the third recessed region in plan view.

9. A method for manufacturing a light detection device, the light detection device including:
a semiconductor substrate in which a plurality of pixels capable of generating an electric signal according to light incident from an outside is arranged in a matrix;
a pixel isolation section provided in the semiconductor substrate to isolate the pixels adjacent to each other; and
an on-chip lens arranged on a light incident surface side of the semiconductor substrate for each pixel group including at least two of the plurality of pixels, the on-chip lens being configured to condense the light from the outside onto the pixel group, the method comprising:
a first process of forming an intra-pixel group isolation section between the pixels adjacent to each other of the pixel group and including a first recessed region extending in a thickness direction of the semiconductor substrate and a second recessed region located at a focal position of the light condensed by the on-chip lens, the second recessed region being different from the first recessed region, wherein
in the first process, the second recessed region is formed narrower than the first recessed region in plan view.

10. The method for manufacturing a light detection device according to claim 9, further comprising:
a second process of filling the second recessed region with a first film; and
a third process of filling the first recessed region with a second film different from the first film.

11. The method for manufacturing a light detection device according to claim 10, wherein
the second film includes a metal film, and
the first film includes a film other than the metal film.

12. A light detection device comprising:
a semiconductor substrate in which a plurality of pixels capable of generating an electric signal according to light incident from an outside is arranged in a matrix;
a pixel isolation section provided in the semiconductor substrate to isolate the pixels adjacent to each other; and
an on-chip lens arranged on a light incident surface side of the semiconductor substrate for each pixel group including at least two of the plurality of pixels, the on-chip lens being configured to condense the light from the outside onto the pixel group, wherein
the pixel isolation section includes
an intra-pixel group isolation section arranged between the pixels adjacent to each other and having an opening at least in a part of a focal position of the light condensed by the on-chip lens,
the on-chip lens is arranged to be shifted in a predetermined direction from a center of the pixel group according to a pupil correction position, and
a formation position of the opening of the intra-pixel group isolation section is shifted according to the pupil correction position.

13. The light detection device according to claim 12, wherein the intra-pixel group isolation section changes an extension distance in a row direction or a column direction of the intra-pixel group isolation section according to the pupil correction position.

14. The light detection device according to claim 12, further comprising
a charge accumulation section formed in the semiconductor substrate and configured to store a charge generated by each of the pixels, wherein
a formation position of the charge accumulation section is shifted according to the pupil correction position.

15. An electronic apparatus comprising a light detection device, the light detection device including:
a semiconductor substrate in which a plurality of pixels capable of generating an electric signal according to light incident from an outside is arranged in a matrix;
a pixel isolation section provided in the semiconductor substrate to isolate the pixels adjacent to each other; and
an on-chip lens arranged on a light incident surface side of the semiconductor substrate for each pixel group including at least two of the plurality of pixels, the on-chip lens being configured to condense the light from the outside onto the pixel group, wherein
the pixel isolation section includes
an intra-pixel group isolation section arranged between the pixels adjacent to each other of the pixel group and including a first recessed region extending in a thickness direction of the semiconductor substrate and a second recessed region located at a focal position of the light condensed by the on-chip lens, the second recessed region being different from the first recessed region, and
in the intra-pixel group isolation section, the second recessed region is formed narrower than the first recessed region in plan view.

16. An electronic apparatus comprising a light detection device, the light detection device including:
a semiconductor substrate in which a plurality of pixels capable of generating an electric signal according to light incident from an outside is arranged in a matrix;
a pixel isolation section provided in the semiconductor substrate to isolate the pixels adjacent to each other; and
an on-chip lens arranged on a light incident surface side of the semiconductor substrate for each pixel group including at least two of the plurality of pixels, the on-chip lens being configured to condense the light from the outside onto the pixel group, wherein
the pixel isolation section includes
an intra-pixel group isolation section arranged between the pixels adjacent to each other of the pixel group and having an opening at least in a part of a focal position of the light condensed by the on-chip lens,
the on-chip lens is arranged to be shifted in a predetermined direction from a center of the pixel group according to a pupil correction position, and
a formation position of the opening of the intra-pixel group isolation section is shifted according to the pupil correction position.
